(19) United States
(12) Patent Application Publication
(10) Pub. No.: US 2005/0106808 A1
(43) Pub. Date: May 19, 2005

(54) Semiconductor devices having at least one storage node and methods of fabricating the same

(76) Inventors: Suk-Won Yu, Seoul (KR); Kyung-Seok Oh, Gyeonggi-do (KR); Joo-Sung Park, Gyeonggi-do (KR); Jung-Hyun Shin, Gyeonggi-do (KR)

Correspondence Address: MARGER JOHNSON & MCCOLLOM, P.C., 1030 SW MORRISON STREET, PORTLAND, OR, 97205, US

(21) Appl. No.: 10/991,260

(22) Filed: Nov. 16, 2004

(30) Foreign Application Priority Data
Nov. 17, 2003 (KR) 2003-81253

(51) Int. Cl. H01L 21/8242

(52) U.S. Cl. 438/253

(57) ABSTRACT

A semiconductor device and methods of fabricating the semiconductor device, suitable for preventing electrical bridges between storage nodes without the increase of planar areas. In one embodiment, a semiconductor device comprises a semiconductor substrate and at least one storage node formed over the semiconductor substrate. The storage node has a bottom portion and a sidewall extending upward from a rim of the bottom portion. At least a portion of the sidewall is recessed.

### CROSS-REFERENCE TO RELATED APPLICATION

This patent application claims priority from Korean Patent Application No. 10-2003-0081253, filed Nov. 17, 2003, the contents of which are hereby incorporated by reference in their entirety.

### BACKGROUND OF THE INVENTION

1. Field of the Invention

The invention relates to semiconductor devices and methods of fabricating thereof, and more particularly, to semiconductor devices having at least one storage node and methods of fabricating thereof.

2. Description of the Related Art

Generally, a semiconductor device having a memory function typically has at least one capacitor in order to store data input by a user. The capacitor includes a lower electrode (hereinafter, referred to as “a storage node”), an upper electrode, and a dielectric layer interposed between the two electrodes.

Depending on the structure of the storage node, the capacitor can be classified as a planar type, a trench type, a stack type, and a cylinder type transformed from the stack type. The dynamic RAM has employed the structures of the storage node in the order listed above, and has increased its integration degree with a concurrent reduction of design rules.

Further, the semiconductor device having at least one cylinder-type storage node is now in mass production in order to cope with the consumers' need for lower costs. To do this, a large number of semiconductor devices should be formed on a single semiconductor substrate with a reduced design rule and without an electrical bridge between storage nodes.

However, since the storage nodes are formed on a semiconductor substrate so that the intervals between the nodes become narrower than before the design rule was reduced, the unwanted electrical bridges between the storage nodes may occur more easily due to the effect of a semiconductor fabrication process. Further, with the reduction of the design rule, the more a contact area of the storage nodes and the semiconductor substrate become reduced, the higher the probability that the storage nodes will fall over on the semiconductor substrate, i.e., a leaning phenomenon.

The design rule employed in the storage nodes determines the size of one selected storage node on the semiconductor substrate, and the intervals between the selected storage node and adjacent storage nodes. Thus, there is a need for a solution in the semiconductor fabrication process to prevent the leaning phenomenon of the storage nodes with the design rule of the storage nodes.

U.S. Pat. No. 6,136,643 to Erik S. Jeng, et. al (the '643 patent) discloses a method of fabricating capacitor-over-bit-line dynamic random access memory (DRAM). According to the '643 patent, the method includes forming self-aligned contact holes between a semiconductor substrate and storage nodes having a Capacitor-Over-Bit-line structure (bottom electrodes). Further, the self-aligned contact holes are respectively filled with landing plugs to fabricate DRAM cells.

However, the method of the '643 patent forms two adjacent storage nodes to face each other with the same height of sidewalls. This method may provide a DRAM cell with a difficulty in avoiding the leaning phenomenon of the storage nodes due to the effect of the semiconductor fabrication process with the reduction of the design rule.

### SUMMARY OF THE INVENTION

According to some embodiments of the invention, there are provided semiconductor devices suitable for preventing the bridges between storage nodes without the increase of planar areas. And there are provided methods of fabricating semiconductor devices capable of increasing the actual interval between storage nodes without the increase of planar areas.

### BRIEF DESCRIPTION OF THE DRAWINGS

Exemplary embodiments of the invention will be readily apparent to those of ordinary skill in the art upon review of the detailed description that follows when taken in conjunction with the accompanying drawings, in which like reference numerals denote like parts.

FIG. 1 is a layout of a semiconductor device according to an embodiment of the invention.

FIGS. 2 and 3 are sectional views taken along lines of I-I′ and II-II′ of FIG. 1, respectively.

FIG. 4 is a layout of a semiconductor device according to another embodiment of the invention.

FIGS. 5 and 6 are sectional views taken along lines of I-I′ and II-II′ of FIG. 4, respectively.

FIG. 7 is a layout of a semiconductor device according to yet another embodiment of the invention.

FIGS. 8 and 9 are sectional views taken along lines of I-I′ and II-II′ of FIG. 7, respectively.

FIG. 10 is a layout of a semiconductor device according to still another embodiment of the invention.

FIGS. 11 and 12 are sectional views taken along lines of I-I′ and II-II′ of FIG. 10, respectively.

FIG. 13 is a layout of a semiconductor device according to yet another embodiment of the invention.

FIGS. 14 and 15 are sectional views taken along lines of I-I′ and II-II′ of FIG. 13, respectively.

FIGS. 16 and 17 are sectional views taken along lines of III-III′ and IV-IV′ of FIG. 13, respectively.

FIGS. 18 to 23 are sectional views illustrating a method of fabricating a semiconductor device of the invention.

FIGS. 24 and 26 are sectional views taken along line of I-I′ of FIG. 1, respectively.

FIGS. 25 and 27 are sectional views taken along line of II-II′ of FIG. 1, respectively.

FIGS. 28 and 30 are sectional views taken along line of I-I′ of FIG. 4, respectively.

FIGS. 29 and 31 are sectional views taken along line of II-II′ of FIG. 4, respectively.

FIGS. 32 and 34 are sectional views taken along line of I-I′ of FIG. 7, respectively.

FIGS. 33 and 35 are sectional views taken along line of II-II′ of FIG. 7, respectively.

FIGS. 36 and 38 are sectional views taken along line of I-I′ of FIG. 10, respectively. and

FIGS. 37 and 39 are sectional views taken along line of II-II′ of FIG. 10, respectively.

### DETAILED DESCRIPTION OF THE PREFERRED EMBODIMENTS

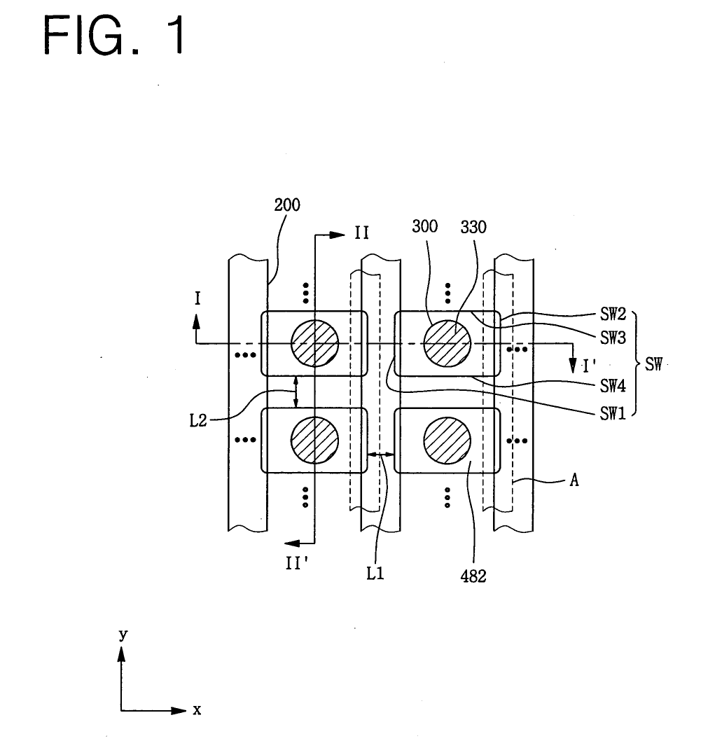

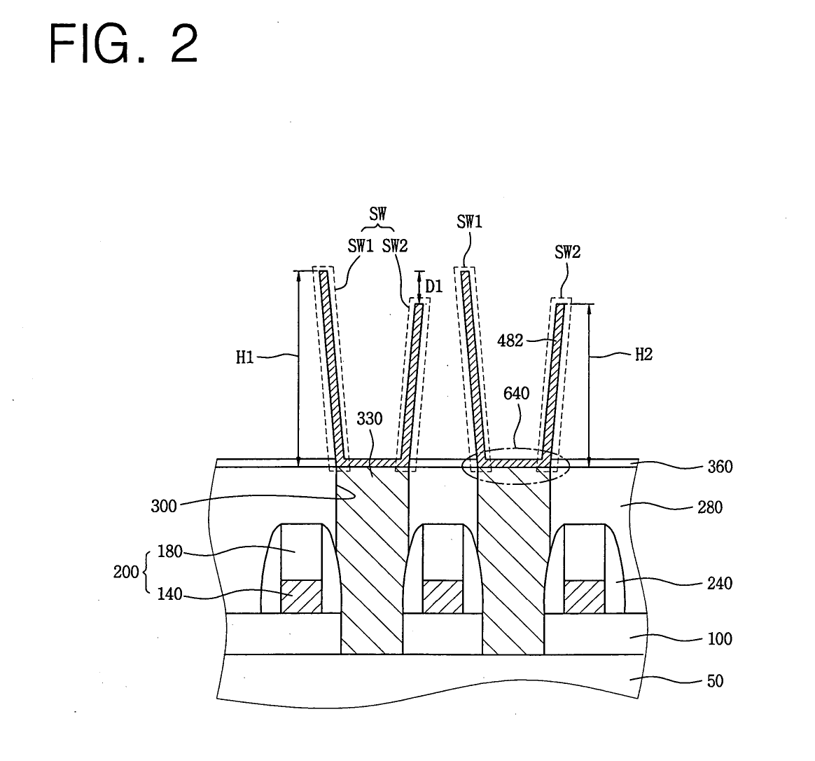

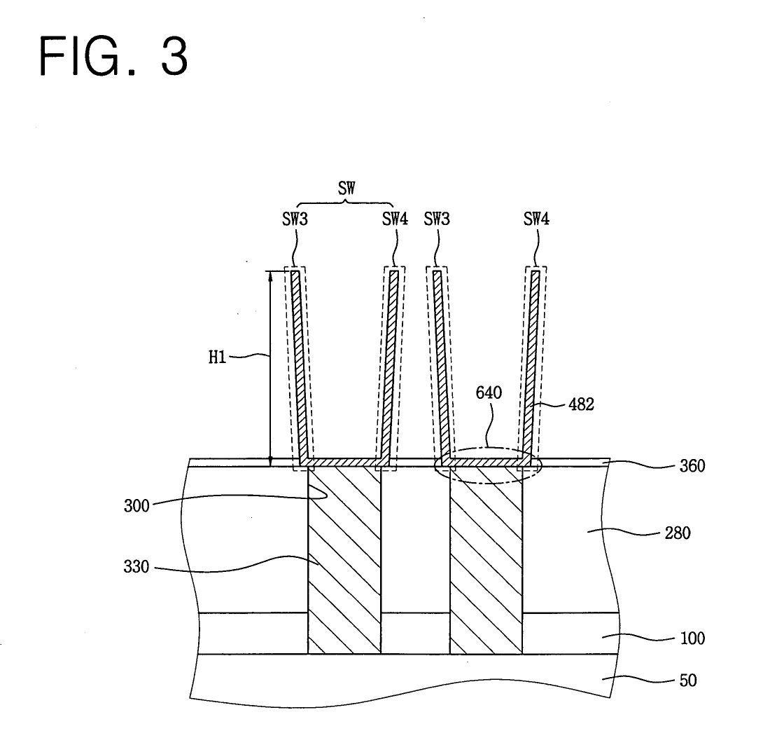

FIG. 1 is a layout of a semiconductor device according to an embodiment of the invention, and FIGS. 2 and 3 are sectional views taken along lines of I-I′ and II-II′ of FIG. 1, respectively.

Referring to FIGS. 1 to 3, a bit line interlayer insulating layer 100 covers a semiconductor substrate 50, and bit line patterns 200 are placed on the bit line interlayer insulating layer 100. Bit line spacers 240 are respectively placed on the side walls of the bit line patterns 200. The bit line spacer 240 is an insulating layer having an etching ratio different from the bit line interlayer insulating layer 100, and each of the bit line patterns 200 preferably includes a bit line 140 and a bit line capping layer pattern 180 stacked thereon. Preferably, the bit line capping layer pattern 180 is an insulating layer having substantially the same etching ratio as the bit line spacer 240, and the bit line 140 includes a doped polysilicon layer and a metal silicide layer stacked thereon. Further, the bit line 140 may be a metal layer having a high melting point. The bit line interlayer insulating layer 100 is preferably an oxide layer.

A buried interlayer insulating layer 280 is placed over the semiconductor substrate 50 having the bit line patterns 200, and at least one buried contact hole 300 is placed between the bit line patterns 200, while penetrating the buried interlayer insulating layer 280 and the bit line interlayer insulating layer 100. The buried contact hole 300 is filled with a buried contact hole pad 330. Preferably, the buried contact hole pad 330 is a doped polysilicon layer, and the buried interlayer insulating layer 280 is an insulating layer having substantially the same etching ratio as the bit line interlayer insulating layer 100.

A storage node 482, which is a cylindrical-type, is placed on the buried contact hole pad 330. The storage node 482 includes a bottom portion 640 electrically connected to the buried contact hole pad 330, and a cylindrical-type sidewall SW (the cylindrical-type sidewall will be referred to as “sidewall SW”) extending from the rim of the bottom portion 640 toward a direction opposite to the semiconductor substrate 50 (upward in FIGS. 2 and 3). As shown in FIG. 1, the interval between two storage nodes 482 can be classified into a first interval L1 along the X-axis direction, and a second interval L2 along in the Y-axis direction. If the first interval L1 is smaller than the second interval L2, the sidewall SW preferably includes a first side wall SW1 and a second side wall SW2, each with a different height, facing each other as shown in FIG. 2. That is, the first side wall SW1 has a first height H1, and the second side wall SW2 has a second height H2 shorter than the first height H1.

Further, as shown in FIG. 2, in the two adjacent storage nodes 482, which can be referred to as a first storage node and a second storage node in the order to the right from the left, the second side wall SW2 of the first storage node is adjacent to the first side wall SW1 of the second storage node. Thus, there exists a step difference D1 between the first and the second storage nodes 482. Particularly, if the sidewall SW has an inclined profile so that the upper width of the storage node 482 is greater than the lower width thereof, the actual interval between the two adjacent first and second side walls SW1, SW2 is further increased due to the height difference D1. On the other hand, in FIG. 3, the sidewall SW of the storage node 482 further includes a third side wall and a fourth side wall SW3, SW4, which face each other. In this case, the third and the fourth side walls SW3, SW4 may have the same height as the first height H1. Therefore, even if the storage nodes 482 are fallen down, the probability of electrical bridges occurring between them can be significantly decreased compared to the conventional technology.

Therefore, it is to be noted that the sidewall SW (without a space between the word “side” and the word “wall”) indicates an entire sidewall of the storage node 482, formed as cylinder-typed, and is formed by four side walls SW1 through SW4 (with a space between the word “side” and the word “side.”) In further detail, describing a semiconductor device having the layout of FIG. 1, the semiconductor device includes a plurality of cylindrical-type storage nodes 482 in a two-dimensional array along columns and rows over the semiconductor substrate 50. Each of the storage nodes 482 includes a first side wall and a second side wall SW1, SW2 in parallel with the rows and facing each other, and a third side wall and a fourth side wall SW3, SW4 in parallel with the columns and facing each other. At least one of the first and the second side walls SW1, SW2 of the storage node 482 is preferably lower in height than the third and the fourth side walls SW3, SW4.

The buried interlayer insulating layer 280 between the storage nodes 482 can be covered with an etch stop layer 360. Preferably, the etch stop layer 360 is an insulating layer having an etching ratio different from the buried interlayer insulating layer 280, and the storage node 482 is a conductive layer such as the buried contact hole pad 330, that is, a doped poly silicon layer.

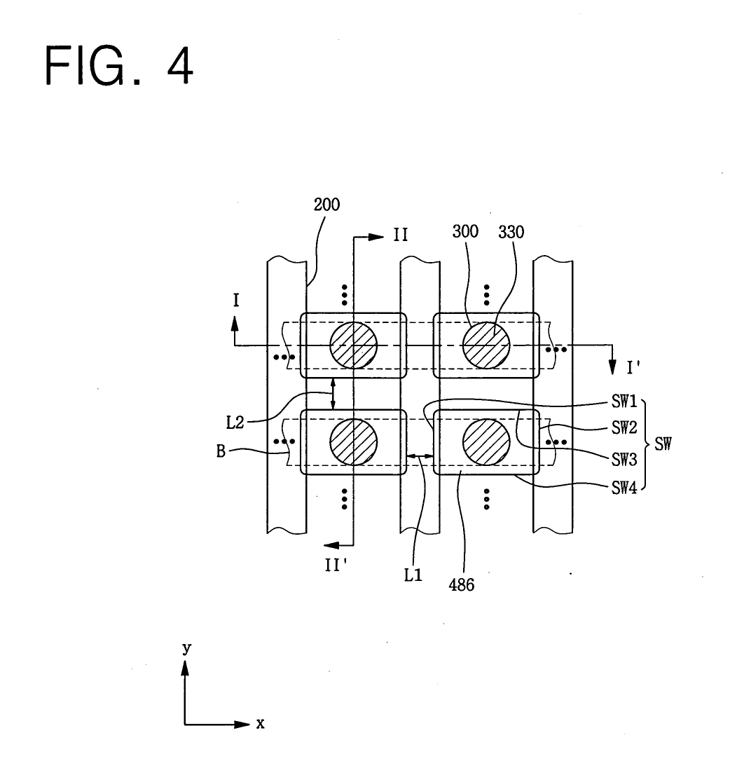

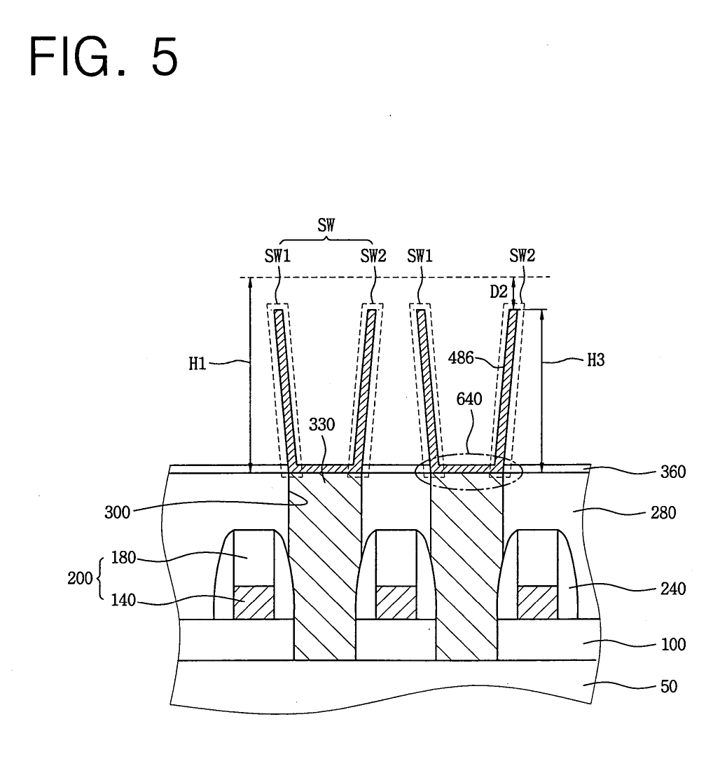

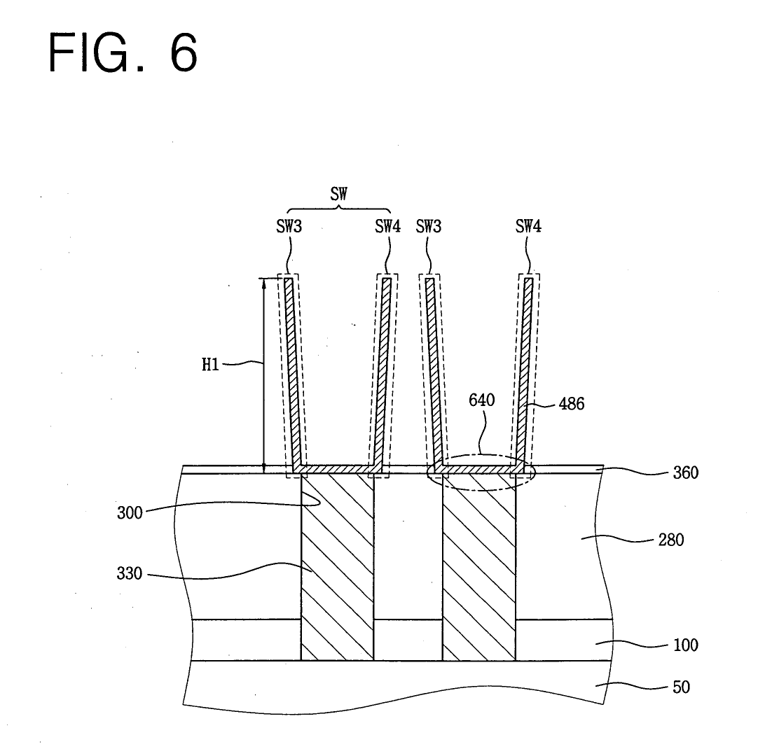

FIG. 4 is a layout of a semiconductor device according to another embodiment of the invention, and FIGS. 5 and 6 are sectional views taken along lines I-I′ and II-II′ of FIG. 4, respectively.

Referring to FIGS. 4 to 6, a cylindrical-type storage node 486 is placed on at least one buried contact hole pad 330. The storage node 486 includes a bottom portion 640 electrically connected to the buried contact hole pad 330, and a sidewall SW extending from the rim of the bottom portion 640 toward a direction opposite to the semiconductor substrate 50 (upward in FIGS. 5 and 6). The interval between two storage nodes 486 can be classified into a first interval L1 along the X-axis direction, and a second interval L2 along the Y-axis direction as shown in FIG. 4. If the first interval L1 is smaller than the second interval L2, the sidewall SW preferably includes a first side wall and a second side wall SW1, SW2, which have the same height H3 and face each other as shown in FIG. 5.

On the other hand, in FIG. 6, the sidewall SW may further include a third side wall and a fourth side wall SW3, SW4, which have the same height H1 and face each other. In this case, the third and the fourth side walls SW3, SW4 have a step difference D2 from the first and the second side walls SW1, SW2 respectively in each storage node.

If the sidewall SW has an inclined profile so that the upper width of the storage node 486 is greater than the lower width thereof, the storage node 486 can have a decreased probability of being fallen down in the X-axis direction of FIG. 4, due to the step difference D2 between the first to the fourth side walls SW1, SW2, SW3, SW4. The reason is that the third height H3 of the first and the second side walls SW1, SW2 is smaller than the first height H1 of the third and the fourth side walls SW3, SW4. Therefore, even if the storage nodes 486 are fallen down, the probability of electrical bridges occurring between them is significantly decreased as compared to the conventional technology.

A buried interlayer insulating layer 280 between the storage nodes 486 can be covered with an etch stop layer 360. Preferably, the etch stop layer 360 is an insulating layer having an etching ratio different from the buried interlayer insulating layer 280, and the storage node 486 is a conductive layer such as the buried contact hole pad 330, that is, a doped polysilicon layer.

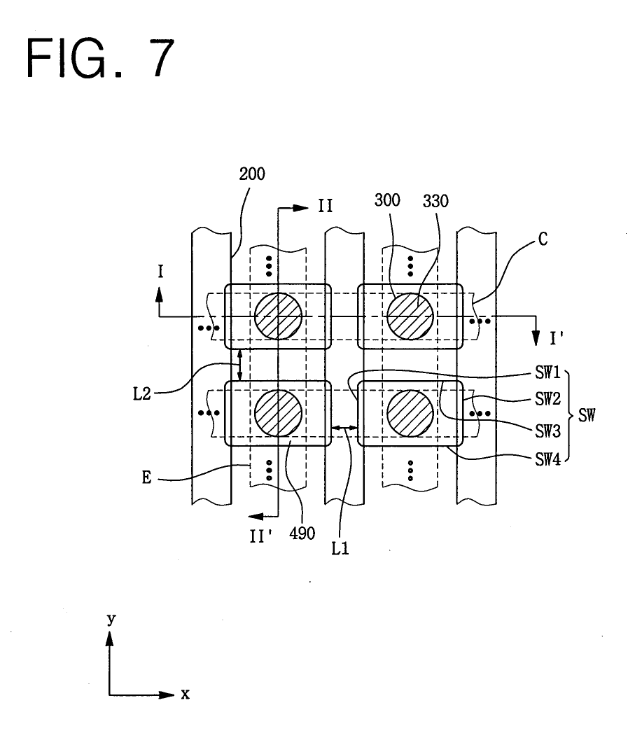

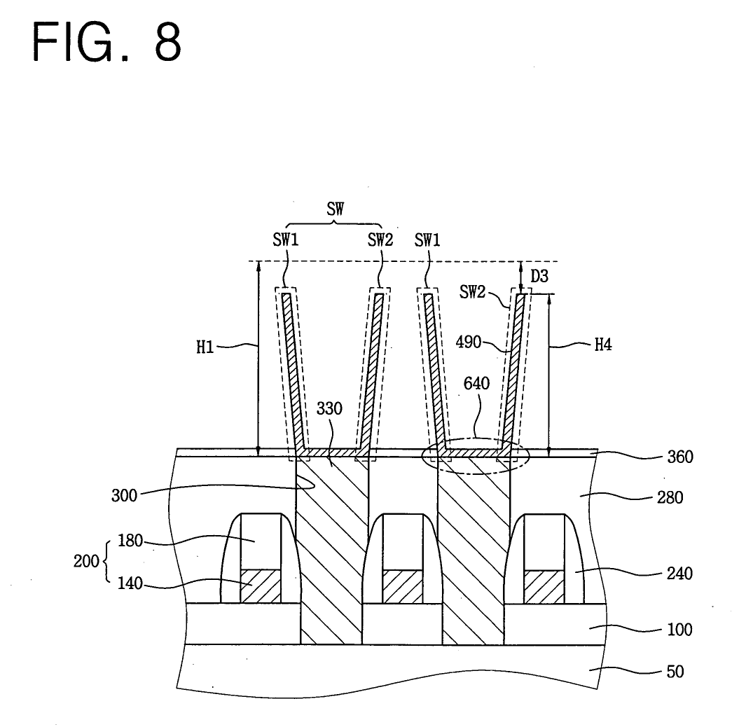

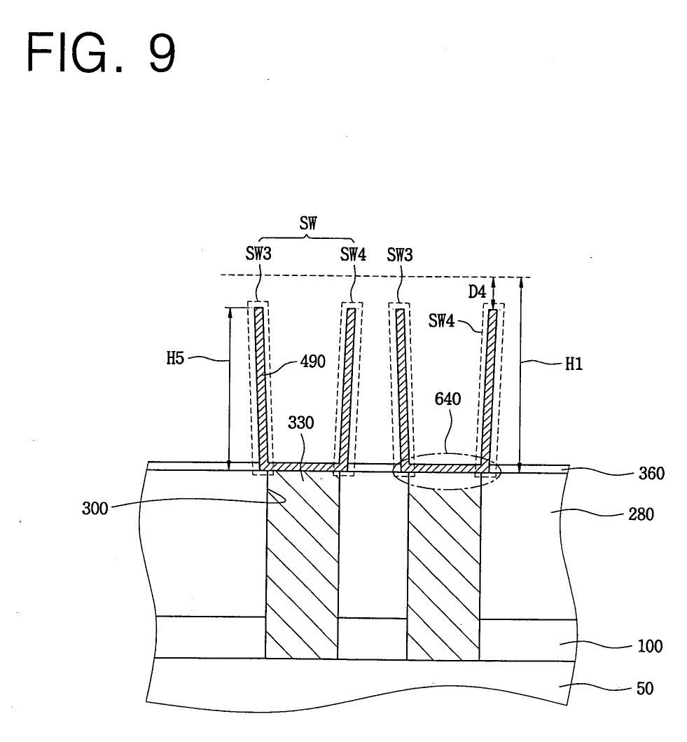

FIG. 7 is a layout of a semiconductor device according to yet another embodiment of the invention, and FIGS. 8 and 9 are sectional views taken along lines I-I′ and II-II′ of FIG. 7, respectively.

Referring to FIGS. 7 to 9, a cylindrical-type storage node 490 is placed on at least one buried contact hole pad 330. The storage node 490 includes a bottom portion 640 electrically connected to the buried contact hole pad 330, and a sidewall SW extending from the rim of the bottom portion 640 toward a direction opposite to the semiconductor substrate 50 (upward in FIGS. 8 and 9). The interval between two storage nodes 490 can be classified into a first interval L1 along the X-axis direction, and a second interval L2 along the Y-axis direction as shown in FIG. 7. The second interval L2 between the storage nodes 490 is preferably smaller than the first interval L1, but may be greater than the first interval L1, or the same. The sidewall SW preferably includes a first side wall and a second side wall SW1, SW2, which have a fourth height H4 and face each other as shown in FIG. 8.

On the other hand, in FIG. 9, the sidewall SW may further include a third side wall and a fourth side wall SW3, SW4, which have a fifth height H5 and face each other. In this case, the fourth height H4 of the first and the second side walls SW1, SW2 may be formed to have a size different from the fifth height H5 of the third and the fourth side walls SW3, SW4. Because of this, the first and the second side walls SW1, SW2 are shorter than the third and the fourth side walls SW3, SW4 of FIG. 6, to form a step difference D3, and the third and the fourth side walls SW3, SW4 are shorter than the side walls of FIG. 6, to form a step difference D4.

Particularly, If the sidewall SW has an inclined profile so that the upper width of the storage node 490 is greater than the lower width thereof, the actual intervals between the two adjacent first and second side walls SW1, SW2 along the X-axis direction of FIG. 7, and between the two adjacent third and fourth side walls SW3, SW4 along the Y-axis direction of FIG. 7 are increased due to the height differences D3, D4 respectively. Therefore, even if the storage nodes 490 are fallen down, the probability of electrical bridges occurring between them is significantly decreased as compared to the conventional technology.

A buried interlayer insulating layer 280 between the storage nodes 490 can be covered with an etch stop layer 360. Preferably, the etch stop layer 360 is an insulating layer having an etching ratio different from the buried interlayer insulating layer 280, and the storage node 490 is a conductive layer such as the buried contact hole pad 330, that is, a doped polysilicon layer.

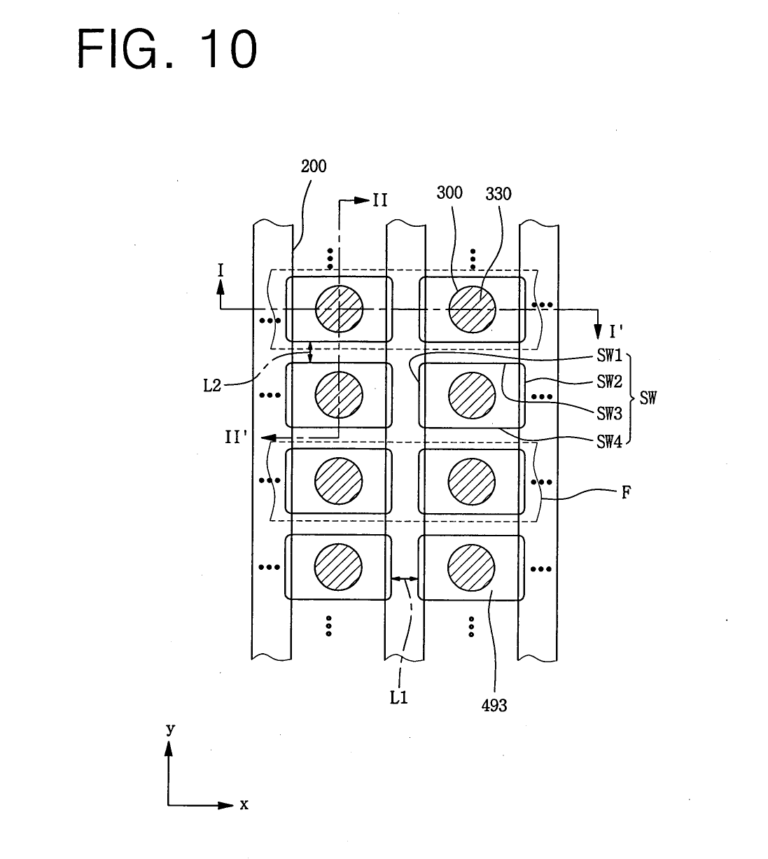

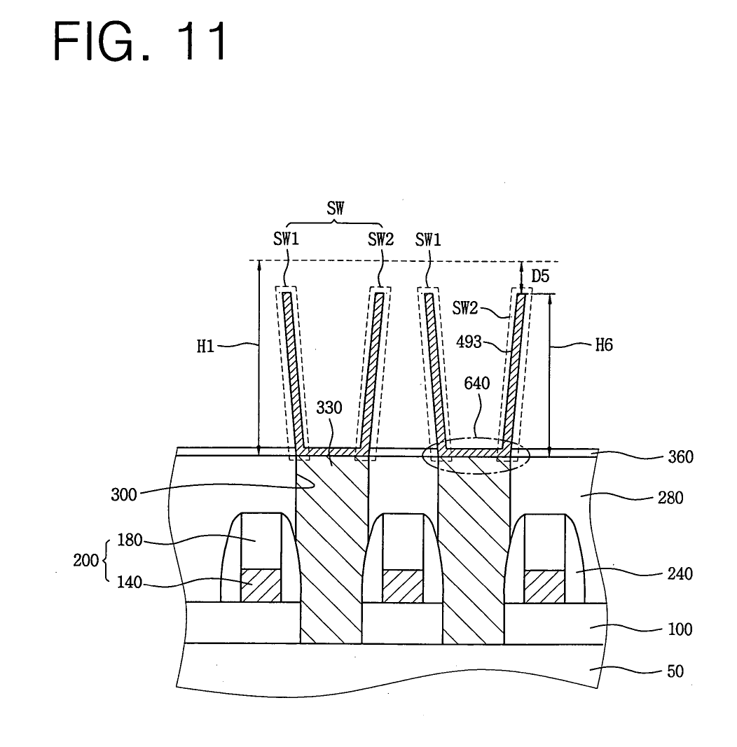

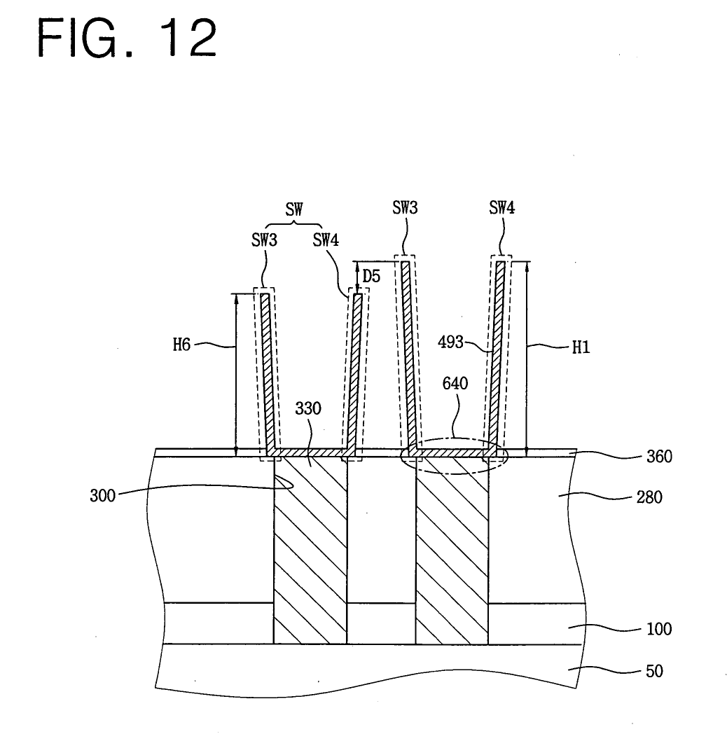

FIG. 10 is a layout of a semiconductor device according to still another embodiment of the invention, and FIGS. 11 and 12 are sectional views taken along lines I-I′ and II-II′ of FIG. 10, respectively.

Referring to FIGS. 10 to 12, a cylindrical-type storage node 493 is placed on at least one buried contact hole pad 330. The storage node 493 includes a bottom portion 640 electrically connected to the buried contact hole pad 330, and a sidewall SW extending from the rim of the bottom portion 640 toward a direction opposite to a semiconductor substrate 50. The interval between two storage nodes 493 can be classified into a first interval L1 along the X-axis direction, and a second interval L2 along the Y-axis direction as shown in FIG. 10. The second interval L2 between the storage nodes 493 is preferably smaller than the first interval L1, but may be greater than the first interval L1, or the same. The sidewall SW preferably includes a first side wall and a second side wall SW1, SW2, which have a sixth height H6 and face each other as shown in FIG. 11. The first and the second side walls SW1, SW2 are lower in height than the third and the fourth side walls SW3, SW4 of FIG. 6, to form a step difference D5.

On the other hand, in FIG. 12, the storage nodes 493, which can be referred to as a first storage node and a second storage node in the order to the right from the left, have heights different from each other, respectively. That is, the first storage node has a third side wall and a fourth side wall SW3, SW4 having a sixth height H6, and the second storage node has a third side wall and a fourth side wall SW3, SW4 having a first height H1. In the two adjacent first and second storage nodes as shown in FIG. 12, the fourth side wall SW4 of the first storage node is adjacent to the third side wall SW3 of the second storage node. As such, there exists a step difference D5 between the storage nodes 493.

Particularly, if the sidewall SW has an inclined profile so that the upper width of the storage node 493 is greater than the lower width thereof, the actual intervals between the two adjacent first and second side walls SW1, SW2, and between the two adjacent third and fourth side walls SW3, SW4 are increased due to the step difference D5. Therefore, even if the storage nodes 493 are fallen down, the probability of electrical bridges occurring between them is significantly decreased as compared to the conventional technology.

In further detail, describing a semiconductor device having the layout of FIG. 10 according to the invention, the semiconductor device includes a plurality of cylindrical-type storage nodes 493 in a two-dimensional array along columns and rows over the semiconductor substrate 50. Herein, the storage nodes 493 include a first group of storage node sidewalls along the even rows, and a second group of storage node sidewalls along the odd rows. Further, the first group of the storage node sidewalls are preferably lower in height than the second group of the storage node sidewalls.

A buried interlayer insulating layer 280 between the storage nodes 493 can be covered with an etch stop layer 360. Preferably, the etch stop layer 360 is an insulating layer having an etching ratio different from the buried interlayer insulating layer 280, and the storage node 493 is a conductive layer such as the buried contact hole pad 330, that is, a doped polysilicon layer.

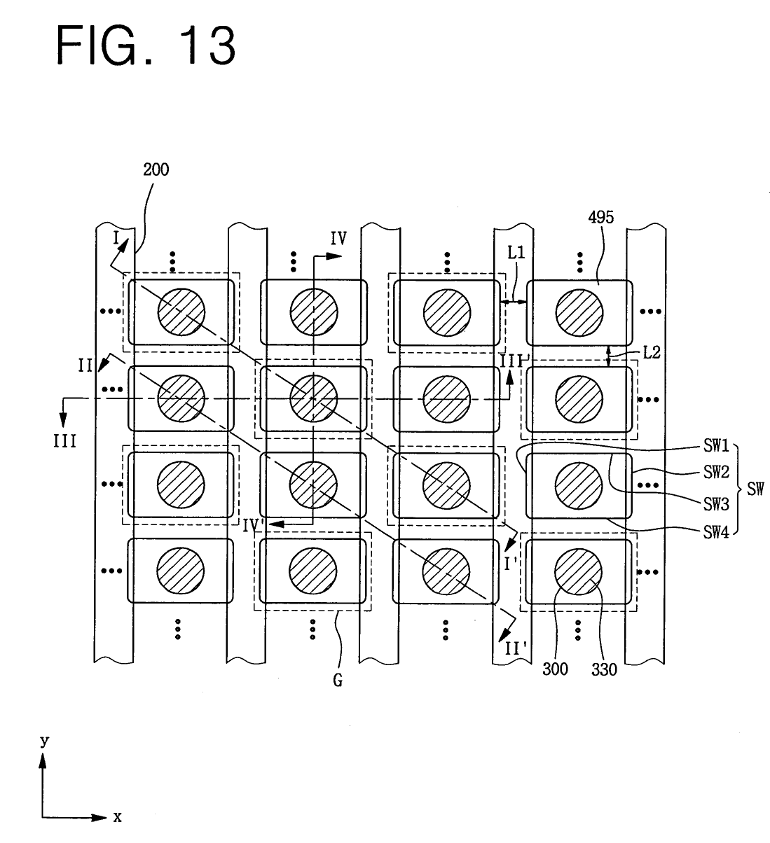

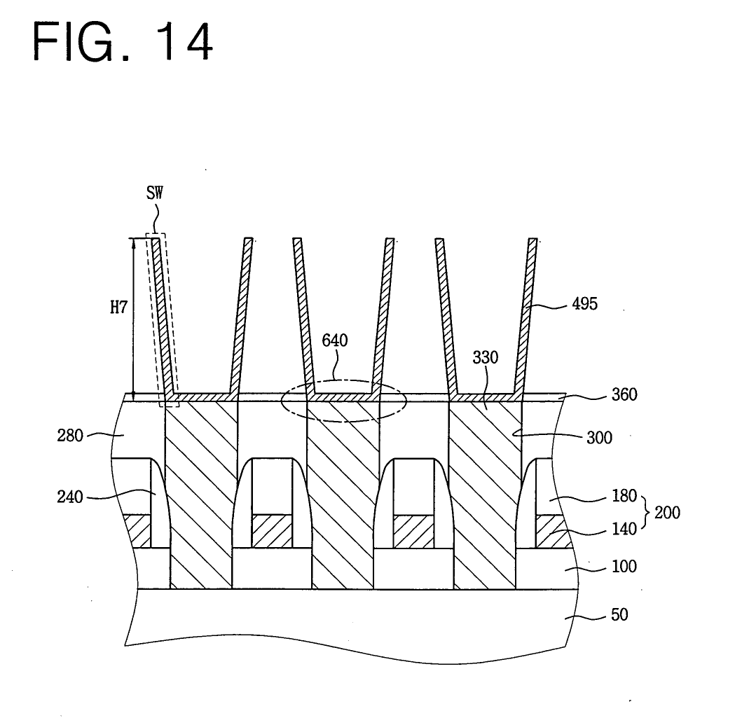

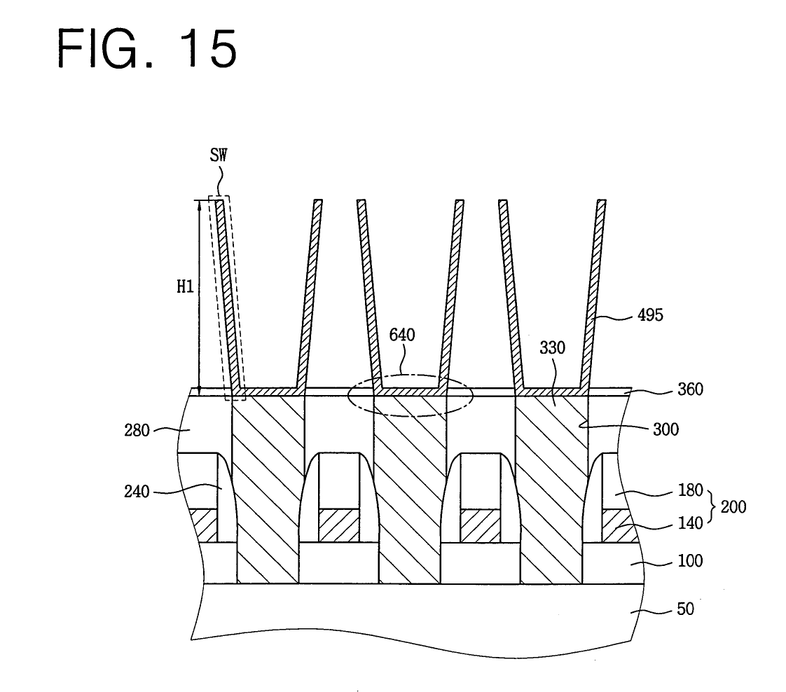

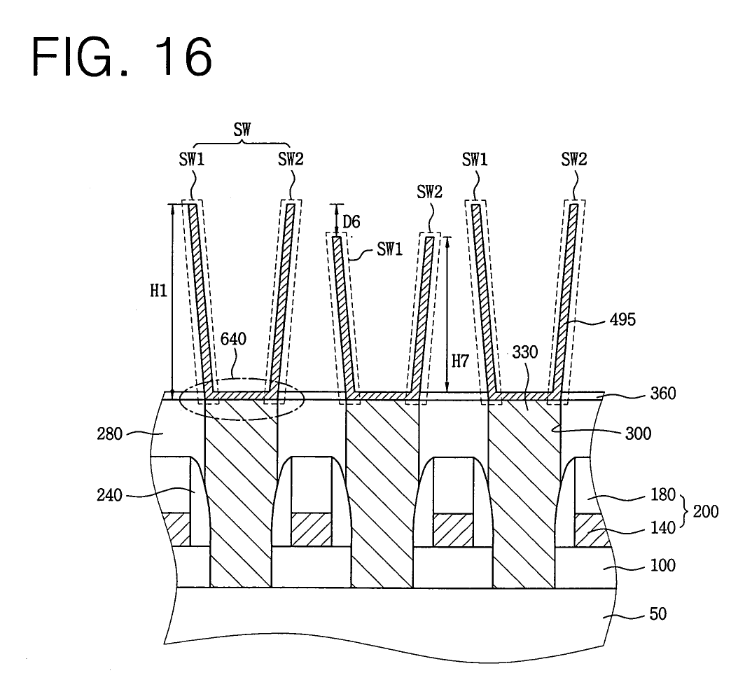

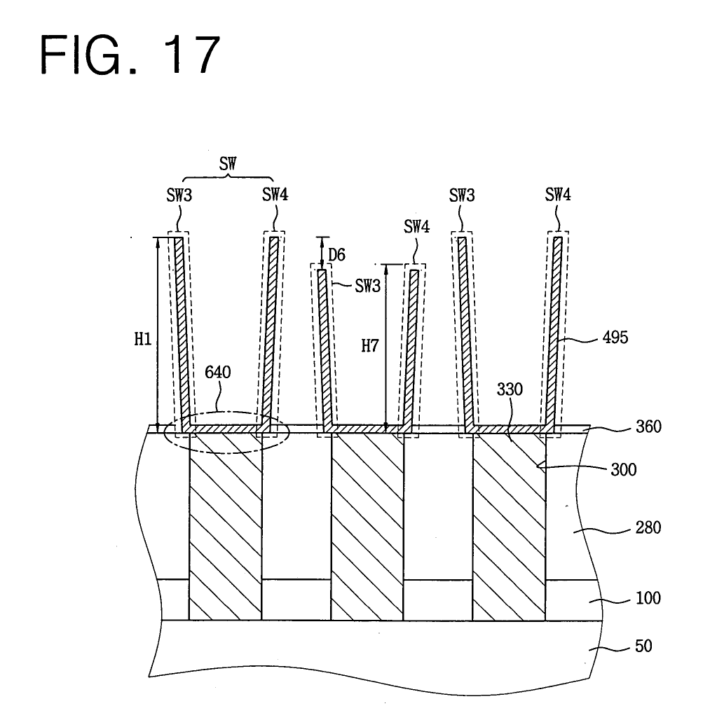

FIG. 13 is a layout of a semiconductor device according to yet another embodiment of the invention, and FIGS. 14 and 15 are sectional views taken along lines I-I′ and II-II′ of FIG. 13, respectively, and FIGS. 16 and 17 are sectional views taken along lines III-III′ and IV-IV′ of FIG. 13, respectively.

Referring to FIGS. 13 through 17, a cylindrical-type storage node 495 is placed on at least one buried contact hole pad 330. Each of the storage nodes 495 includes a bottom portion 640 electrically connected to each of the buried contact hole pads 330, and a sidewall SW extending from the rim of the bottom portion 640 toward a direction opposite to a semiconductor substrate 50. The interval between two storage nodes 495 can be classified into a first interval L1 along the X-axis direction, and a second interval L2 along the Y-axis direction as shown in FIG. 13. The second interval L2 between the storage nodes 495 is preferably smaller than the first interval L1, but may be greater than the first interval L1, or the same. The sidewall SW preferably has a seventh height H7 as shown in FIG. 14. The sidewall SW may have a first height H1, which may be greater than the seventh height H7, as shown in FIG. 15.

Further, as shown in FIG. 16, the storage nodes 495, which can be referred to as a first storage node to a third storage node in the order to the right from the left, include a first side wall and a second side wall SW1, SW2 having a first height H1. At the same time, a second storage node is preferably formed to have a first side wall and a second side wall SW1, SW2 having a seventh height H7. Thus, there exists a step difference D6 between the second side wall SW2 of the first storage node, and the first side wall SW1 of the second storage node. In the same way, there also exists the same step difference D6, as above, between the second side wall SW2 of the second storage node, and the first side wall SW1 of the third storage node.

On the other hand, in FIG. 17, the first storage node and the third storage node have a third side wall and a fourth side wall SW3, SW4 having a first height H1. At the same time, the second storage node can be formed to have a third side wall and a fourth side wall SW3, SW4 having a seventh height H7. As such, there exists a step difference D6 between the fourth side wall SW4 of the first storage node, and the third side wall SW3 of the second storage node. Further, there also exists the height difference D6 between the fourth side wall SW4 of the second storage node, and the third side wall SW3 of the third storage node.

Thus, from the views taken along lines I-I′, II-II′, III-III′, and IV-IV′ of FIG. 13, one selected among the storage nodes 495 is formed to be surrounded by four adjacent other storage nodes 495 in the four directions, having heights different from the respective side walls of the selected storage node. Herein, the selected one storage node 495 has a first height H1 or a seventh height H7, and at the same time, the four adjacent other storage nodes 495 have the seventh height H7 or the first height H1, respectively.

Particularly, if the sidewall SW has an inclined profile so that the upper width of the storage node 495 is greater than the lower width thereof, the actual intervals between the two adjacent first and second storage nodes, and between the two adjacent second and third storage nodes are increased due to the step difference D6 in the sectional views of FIGS. 16 and 17. Therefore, even if the storage nodes 495 are fallen down, the probability of electrical bridges occurring between them is significantly decreased as compared to the conventional technology.

In further detail, describing a semiconductor device having the layout of FIG. 13 according to the invention, the semiconductor device includes a plurality of cylindrical-type storage nodes 495 in a two-dimensional array along columns and rows over the semiconductor substrate 50. Herein, the storage nodes 495 include a first group of storage nodes, which are placed on the cross locations of even rows and even columns, as well as odd rows and odd columns, and a second group of storage nodes, which are placed on the cross locations of even rows and odd columns, and odd rows and even columns other than the above, i.e., adjacent to the first group of storage nodes. The first group of storage nodes is preferably lower in height than the second group of storage nodes.

A buried interlayer insulating layer 280 between the storage nodes 495 can be covered with an etch stop layer 360. Preferably, the etch stop layer 360 is an insulating layer having an etching ratio different from the buried interlayer insulating layer 280, and the storage node 495 is a conductive layer such as the buried contact hole pad 330, that is, a doped polysilicon layer.

Now hereinafter, a method of fabricating semiconductor devices according to the invention will be described in detail with reference to accompanying drawings.

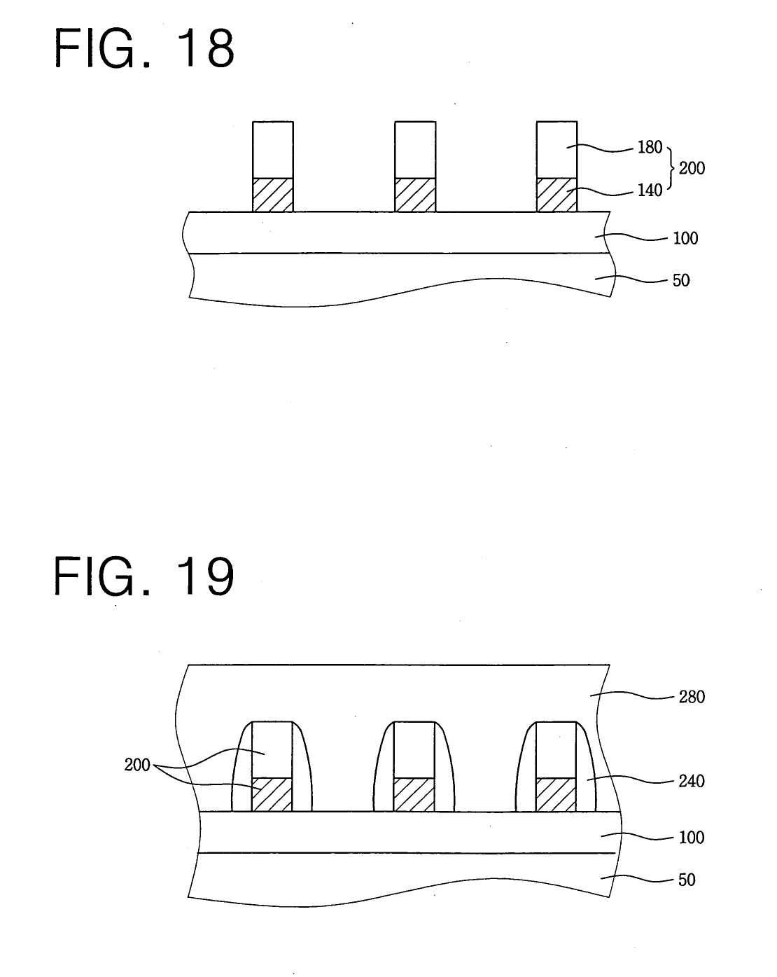

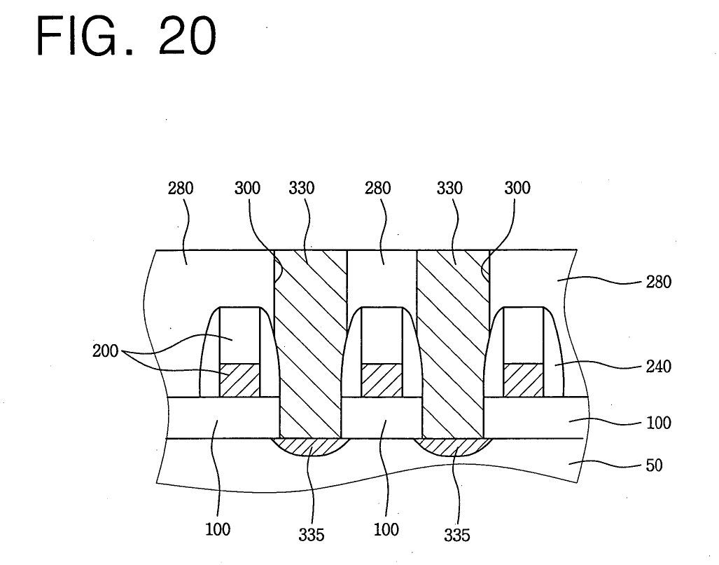

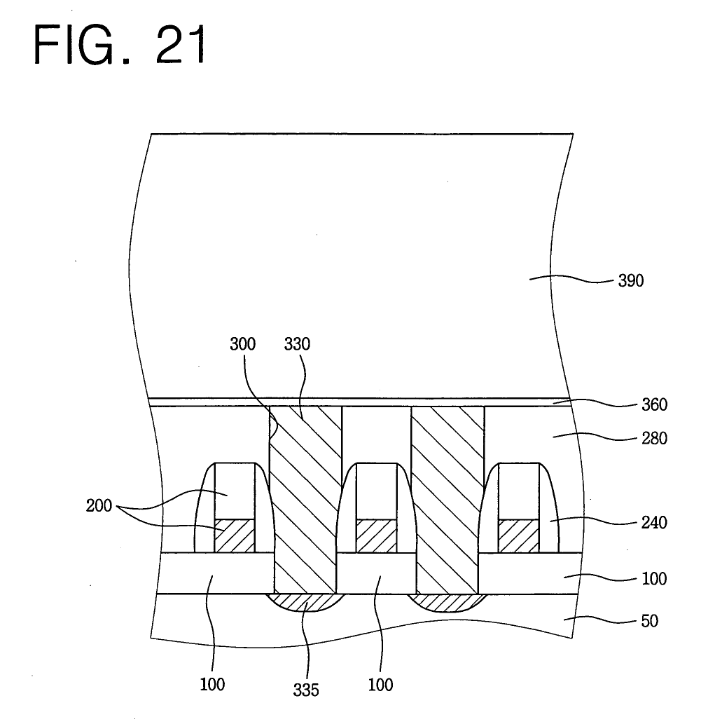

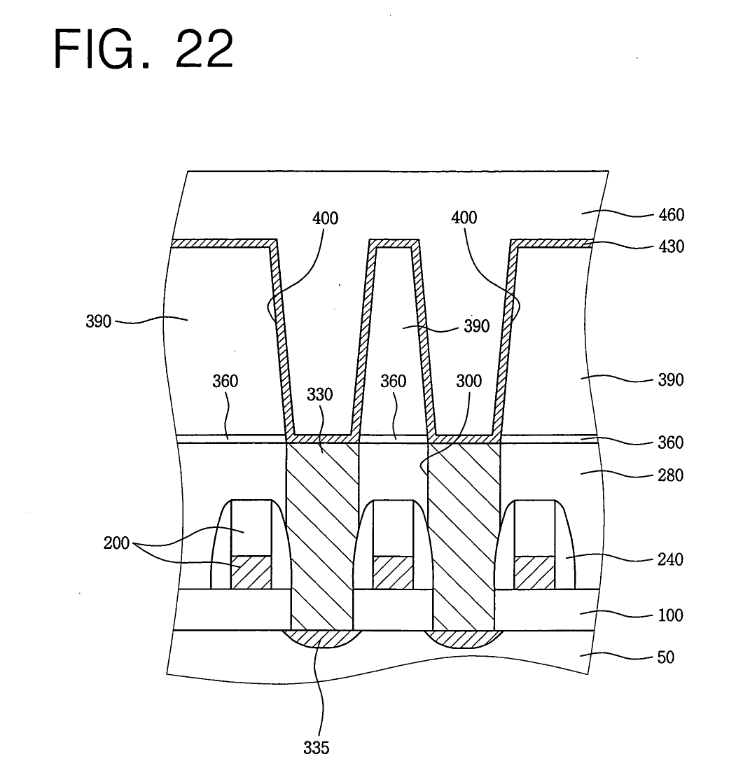

FIGS. 18 to 23 are sectional views illustrating a method of fabricating a semiconductor device of the invention, respectively.

Referring to FIGS. 18 to 23, a bit line interlayer insulating layer 100 is formed on a semiconductor substrate 50, and bit line patterns 200 are formed on the semiconductor substrate 50 having the bit line interlayer insulating layer 100. Bit line spacers 240 are respectively formed on the sidewalls of the bit line patterns 200, and a buried interlayer insulating layer 280 is formed over the bit line interlayer insulating layer 100 to cover the bit line patterns 200 and the bit line spacers 240. At this time, preferably, the bit line interlayer insulating layer 100 is formed of an insulating layer having substantially the same etching ratio as the buried interlayer insulating layer 280, and the bit line spacers 240 are formed of an insulating layer having an etching ratio different from the buried interlayer insulating layer 280. Further, each of the bit line patterns 200 preferably includes a bit line 140 and a bit line capping layer pattern 180 stacked thereon. Preferably, the bit line capping layer pattern 180 is formed of an insulating layer having substantially the same etching ratio as the bit line spacer 240, and the bit line 140 includes a doped poly silicon layer and a metal silicide layer stacked thereon. Further, the bit line 140 may be formed of a metal layer having a high melting point.

Buried contact holes 300 are formed between the bit line patterns 200 to penetrate the buried interlayer insulating layer 280 and the bit line interlayer insulating layer 100. The buried contact holes 300 expose the semiconductor substrate 50. Then, a buried contact hole pad 330 fill buried contact hole 300, respectively. The buried contact hole pads 330 contact the semiconductor substrate 50 to form diffusion layers 335. An etch stop layer 360 and a molding layer 390 are sequentially formed over the semiconductor substrate 50 having the buried contact hole pads 330, and storage contact holes 400 are formed to penetrate the molding layer 390 and the etch stop layer 360 and expose the top surfaces of the buried contact hole pads 330. Herein, each of the storage contact holes 400 is formed to have an inclined profile so that the upper width is greater than the lower width. Preferably, the etch stop layer 360 is formed of an insulating layer having substantially the same etching ratio as the bit line spacer 240, and the molding layer 390 is formed of the same insulating layer as the buried interlayer insulating layer 280. Further, the molding layer 390 is preferably formed of at least one insulating layer. The buried contact hole pads 330 are preferably formed of a conductive layer, that is, doped polysilicon layer.

A storage node layer 430 is conformally formed on the semiconductor substrate 50 having the storage contact holes 400, and a sacrificial layer 460 is formed on the storage node layer 430. Then, a planarization process is performed on the sacrificial layer 460 and the storage node layer 430 until the top surface of the molding layer 390 is exposed to form storage nodes 480 and sacrificial layer patterns 500. The storage nodes 480 and the sacrificial layer patterns 500 fill the storage contact holes 400, respectively. Thus, the storage nodes 480 is surrounded by the molding layer 390 and the sacrificial layer patterns 500 so that the top surfaces thereof is exposed. The sacrificial layer 460 is formed of an insulating layer having substantially the same etching ratio as the molding layer 390, and the storage node layer 430 is preferably formed of a conductive layer such as the buried contact hole pad 330, that is, doped polysilicon layer.

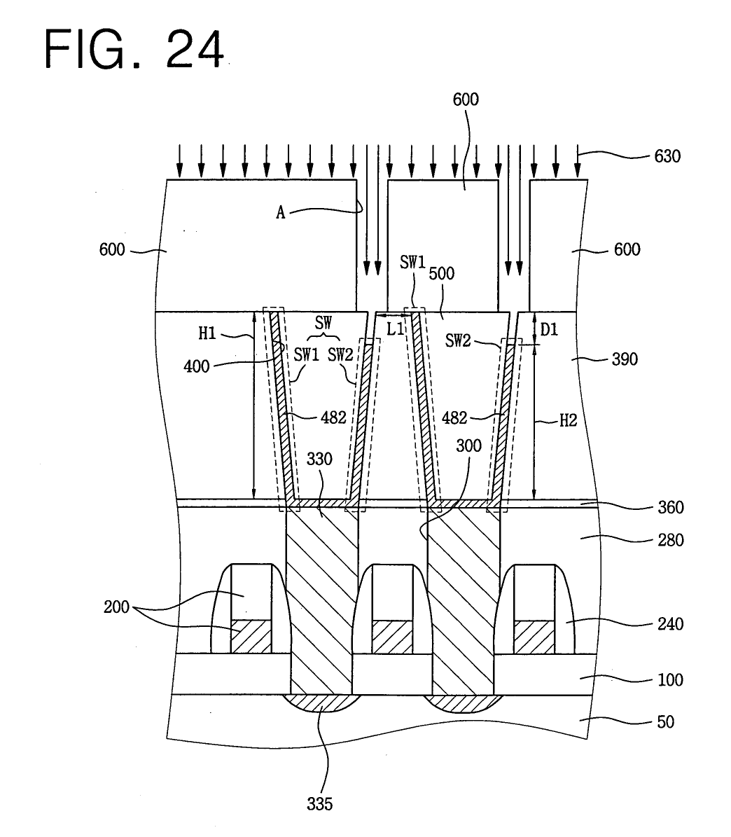

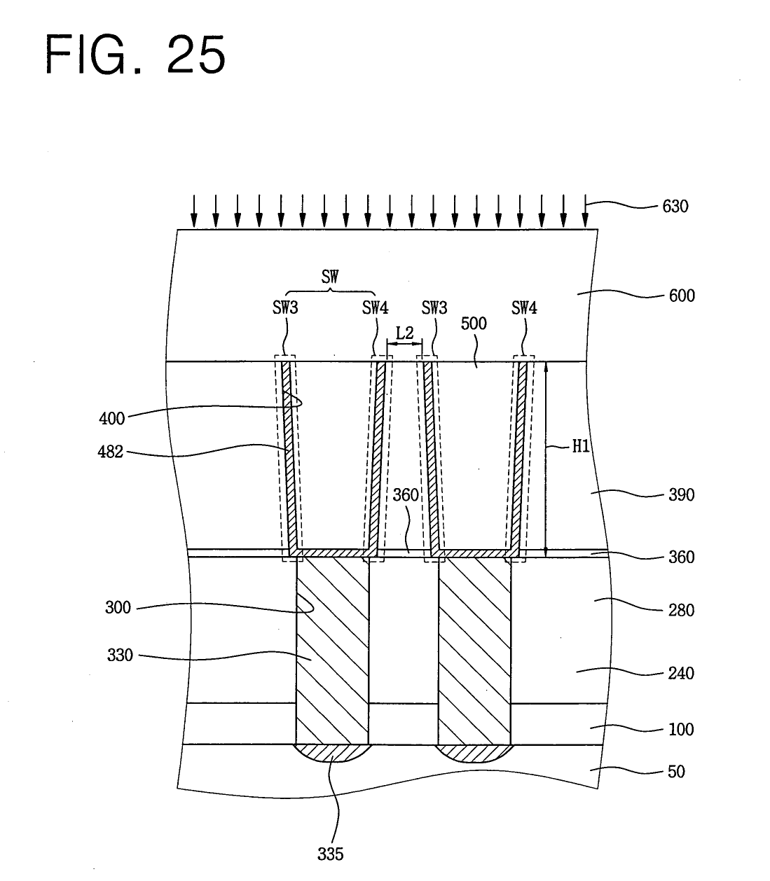

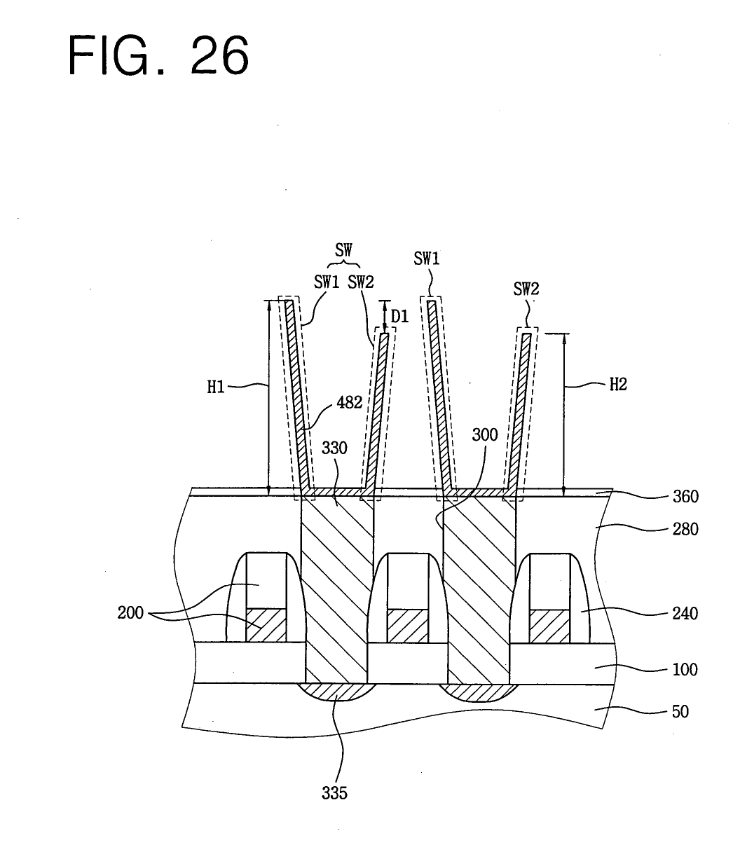

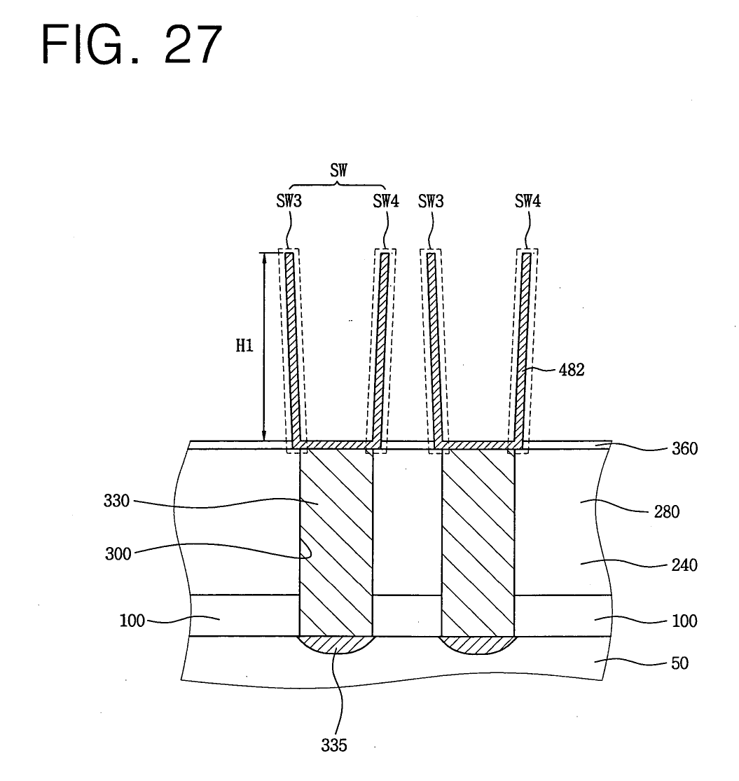

FIGS. 24 and 26 are cross-sectional views taken along line I-I′ of FIG. 1, respectively, and FIGS. 25 and 27 are sectional views taken along line II-II′ of FIG. 1, respectively.

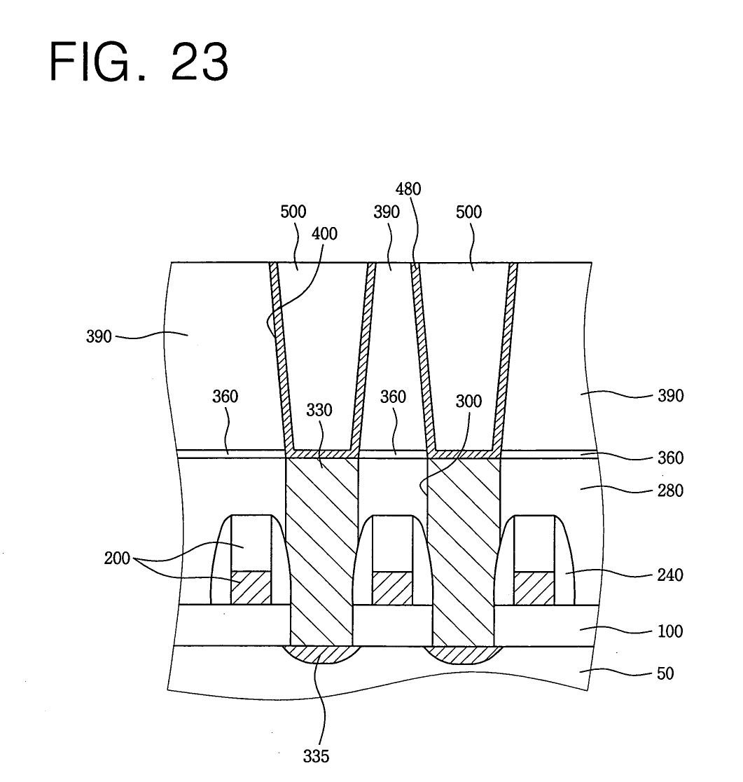

Referring to FIG. 1 and FIGS. 24 to 27, a photoresist layer 600 is formed over the semiconductor substrate 50 having the sacrificial layer patterns 500, and a photolithographic process is performed on the photoresist layer 600 to form storage openings A in the photoresist layer 600. The storage openings A expose the top surfaces of the storage nodes 480 of FIG. 23, respectively. An etch process 630 is performed on the photoresist layer having the storage openings A to partially remove the storage nodes 480 to a predetermined depth, and to form storage nodes 482.

Each of the storage nodes 482 is formed to have an inclined profile so that the upper width is greater than the lower width, and also formed so that a sidewall SW (the cylindrical-type sidewall will be referred to as “sidewall SW”.) includes two pairs of side walls, i.e. first to fourth side walls SW1, SW2, SW3, SW4. Two side walls of each of the two pairs face each other. Herein, preferably, each of the storage openings A overlaps at least one side wall among the first to the fourth side walls SW1, SW2, SW3, SW4 to expose the top surface of the storage node 482.

The intervals between the storage nodes 482 include a first interval L1 along the X-axis direction, and a second interval L2 along the Y-axis direction as shown in FIG. 1. If the first interval L1 is smaller than the second interval L2, the sidewall SW is preferably formed to include a first side wall and a second side wall SW1, SW2 with heights different from each other as shown in FIGS. 24 and 26. That is, the first side wall SW1 has a first height H1, and the second side wall SW2 has a second height H2, being smaller than the first height H1. The first side wall and the second side wall SW1, SW2 face each.

Further, in the two adjacent first and second storage nodes in the order to the left from the right as shown in FIGS. 24 and 26, the second side wall SW2 of the first storage node is adjacent to the first side wall SW1 of the second storage node. Because of this, there exists a step difference D1 between the storage nodes 482, and thus, the actual interval between the first and the second side walls SW1, SW2 is increased due to the step difference D1.

On the other hand, as shown in FIGS. 25 and 27, the sidewall SW of the storage node 482 is preferably formed to include a third side wall and a fourth side wall SW3, SW4 facing each other. In this case, the third and the fourth side walls SW3, SW4 have the same height as the first height H1. Thus, even though the storage nodes 482 are fallen down, the probability of electrical bridges occurring between them is significantly decreased as compared to the conventional technology.

In further detail, describing the storage nodes 482 according to the invention, a plurality of cylindrical-type storage nodes 482 are formed over the semiconductor substrate 50, and formed to be in a two-dimensional array along columns and rows. Herein, each of the storage nodes 482 is formed so that its sidewall SW includes a first side wall and a second side wall SW1, SW2 in parallel with the rows and facing each other, and a third side wall and a fourth side wall SW3, SW4 in parallel with the columns and facing each other. Herein, preferably, each of the storage openings A is formed to overlap at least one of the first to the fourth side walls SW1, SW2, SW3, SW4 to expose the top surface of the storage nodes 482.

The etch process 630 is performed to have an etching ratio with respect to the molding layer 390 and the sacrificial layer patterns 500. Then, after the etch process 630 is performed, the photoresist layer 600 is removed from the semiconductor substrate 50. Then, a wet etch process is performed by using the etch stop layer 360 as a buffer layer to remove the sacrificial layer patterns 500 and the molding layer 390, which contact the inner sidewall and the outer sidewall of the storage node 482, respectively.

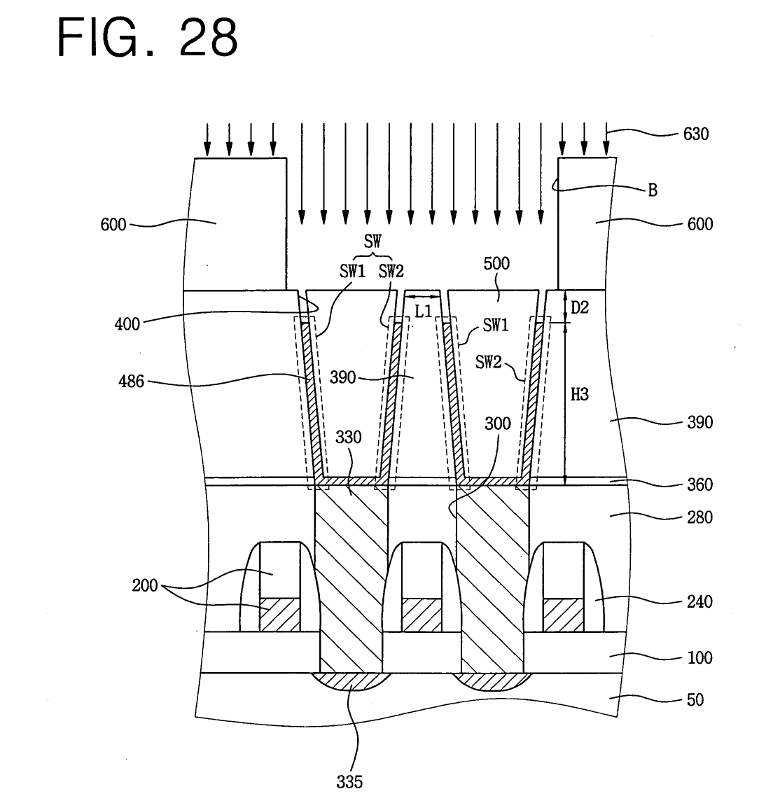

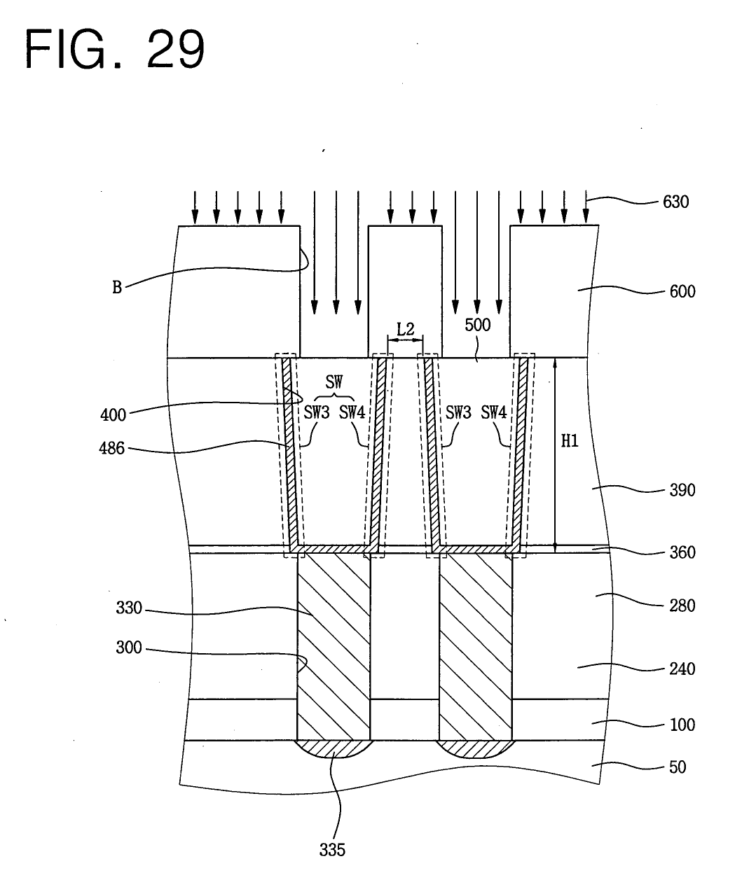

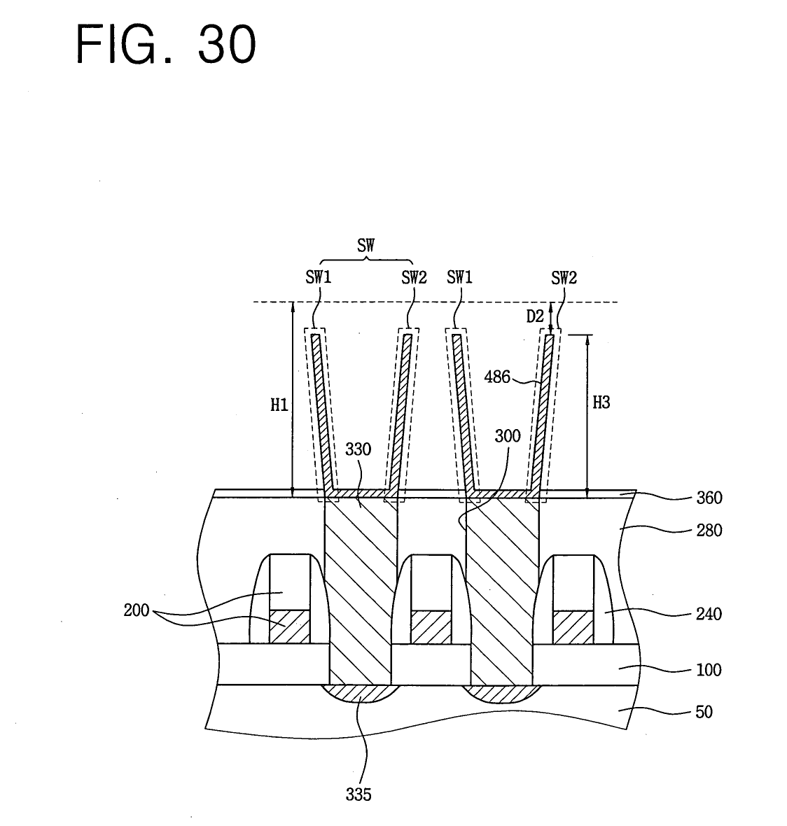

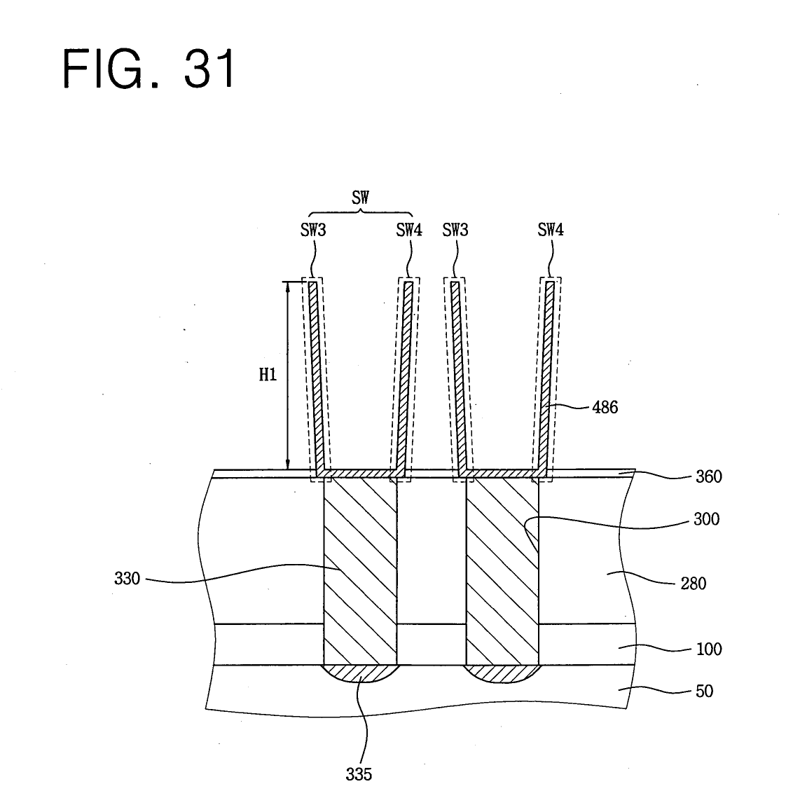

FIGS. 28 and 30 are sectional views taken along line I-I′ of FIG. 4, respectively, and FIGS. 29 and 31 are sectional views taken along line II-II′ of FIG. 4, respectively.

Referring to FIG. 4 and FIGS. 28 to 31, a photoresist layer 600 is formed on a semiconductor substrate 50 having the sacrificial layer patterns 500 of FIG. 23, and a photolithographic process is performed on the photoresist layer 600 to form storage openings B in the photoresist layer 600. The storage openings B expose the top surfaces of the storage nodes 480 of FIG. 23. An etch process 630 is performed on the photoresist layer having the storage openings B to partially remove the storage node 480 to a predetermined depth, and to form storage nodes 486.

Each of the storage nodes 486 is formed to have an inclined profile so that the upper width is greater than the lower width, and at the same time, is formed so that the sidewall SW includes two pairs of side walls, i.e. first to fourth side walls SW1, SW2, SW3, SW4. Two side walls of each of the two pairs face each other. Herein, preferably, each of the storage openings B overlaps one pair of facing side walls among the first to the fourth side walls SW1, SW2, SW3, SW4 to expose the top surfaces of the storage nodes 486.

The intervals between the storage nodes 486 are formed to include a first interval L1 along the X-axis direction, and a second interval L2 along the Y-axis direction as shown in FIGS. 28 and 30. If the first interval L1 is smaller than the second interval L2, the sidewall SW is preferably formed to include a first side wall and a second side wall SW1, SW2 with the same height H3. The first side wall and the second side wall SW1, SW2 face each other.

On the other hand, as shown in FIGS. 29 and 31, the sidewall SW is preferably formed to include a third side wall and a fourth side wall SW3, SW4 facing each other with the same height H1. In this case, there exists a step difference D2 between the third and the fourth side walls SW3, SW4, and the first and the second side walls SW1, SW2.

If the sidewall SW of the storage node 486 has an inclined profile so that the upper width is greater than the lower width, the respective storage node 486 having the first to the fourth side walls SW1, SW2, SW3, SW4 can have a decreased probability of being fallen down in the X-axis direction of FIG. 4 due to the step difference D2. This is because the third height H3 of the first and the second side walls SW1, SW2 is smaller than the first height H1 of the third and the fourth side walls SW3, SW4. Therefore, even if the storage nodes 486 are fallen down, the probability of electrical bridges occurring between them is significantly decreased as compared to the conventional technology.

The etch process 630 is performed to have an etching ratio with respect to the molding layer 390 and the sacrificial layer patterns 500. Then, after the etch process 630 is performed, the photoresist layer 600 is removed from the semiconductor substrate 50. A wet etch process is performed by using the etch stop layer 360 as a buffer layer to remove the sacrificial layer patterns 500 and the molding layer 390, which contact the inner sidewall and the outer sidewall of the storage node 486, respectively.

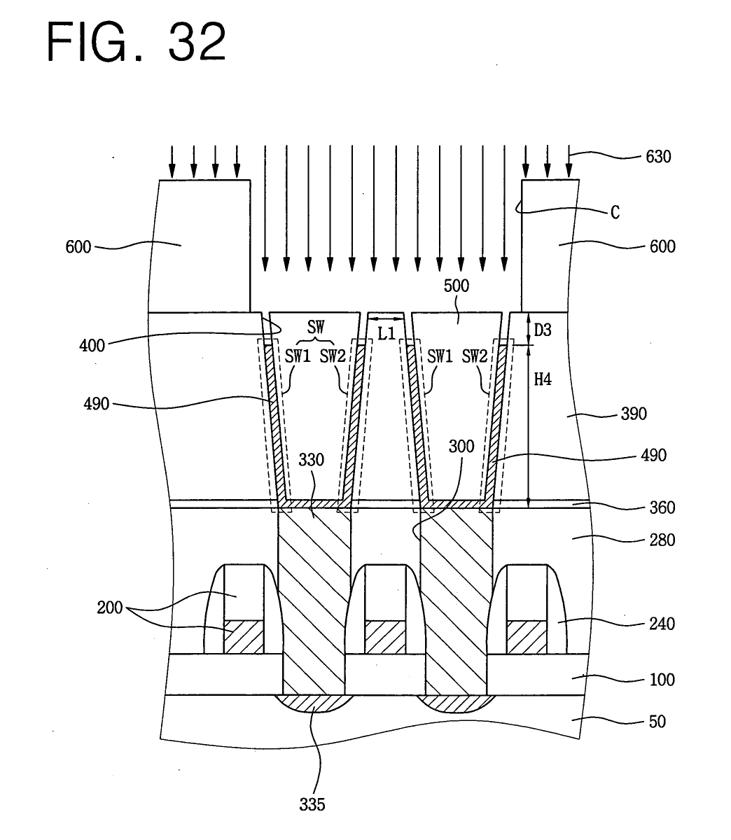

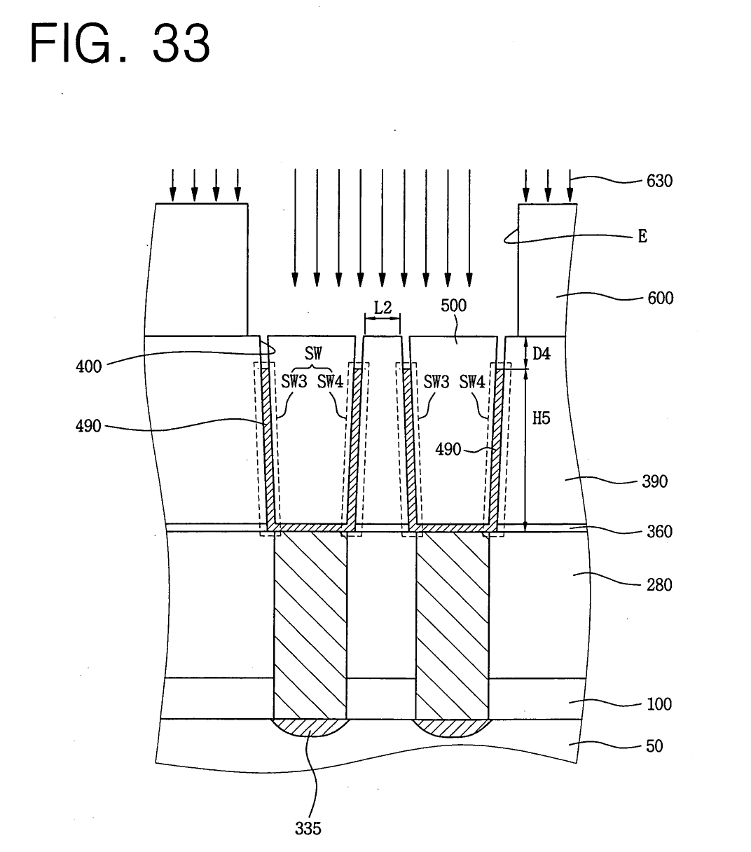

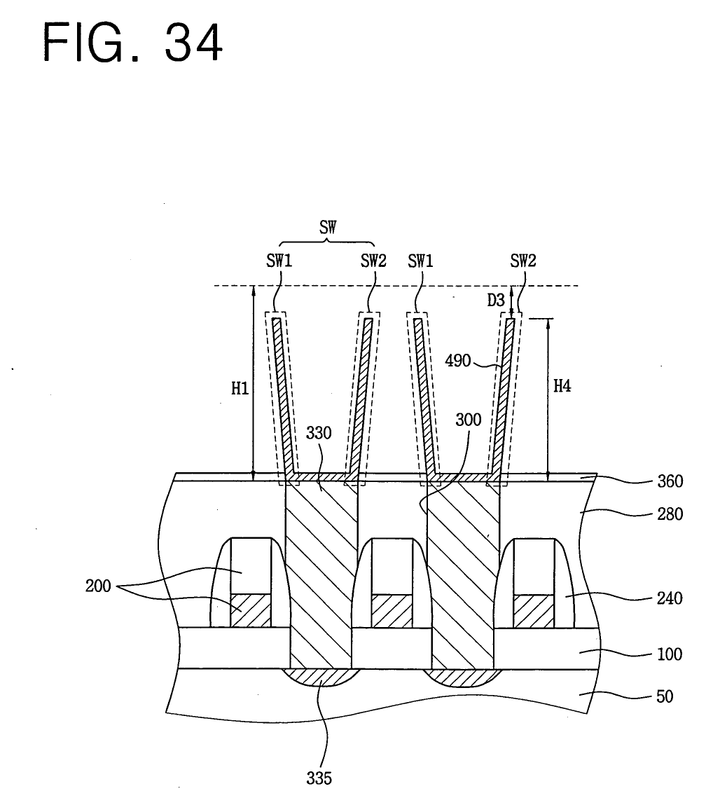

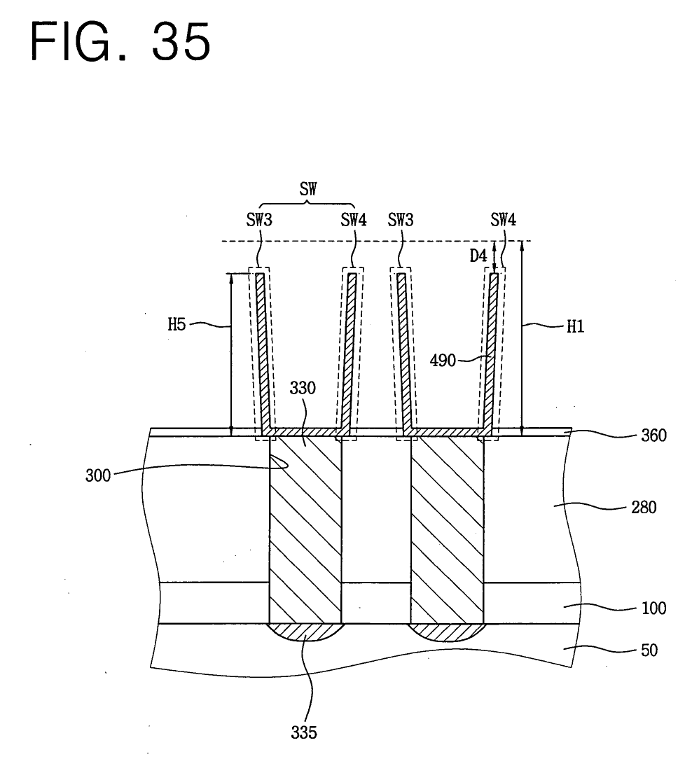

FIGS. 32 and 34 are sectional views taken along line I-I′ of FIG. 7, respectively, and FIGS. 33 and 35 are sectional views taken along line II-II′ of FIG. 7, respectively.

Referring to FIG. 7 and FIGS. 32 to 35, a photoresist layer 600 is formed on a semiconductor substrate 50 having the sacrificial layer pattern 500 of FIG. 23, and a photolithographic process is performed on the photoresist layer 600 to form storage openings C, E in the photoresist layer 600. The storage openings C, E expose the top surfaces of storage nodes 480 of FIG. 23 at the same time. An etch process 630 is performed on the photoresist layer having the storage openings C, E to partially remove the storage node 480 to a predetermined depth, and to form storage nodes 490.

Each of the storage nodes 490 is formed to have an inclined profile so that the upper width is greater than the lower width, and at the same time, is formed so that the sidewall SW includes two pairs of side walls, i.e. first to fourth side walls SW1, SW2, SW3, SW4. Two side walls of each of the two pairs face each other. Herein, preferably, the storage openings C, E overlap two pairs of facing side walls at the same time, the first to the fourth side walls SW1, SW2, SW3, SW4 to expose the top surfaces of the storage nodes 490.

The intervals between the storage nodes 490 are formed to include a first interval L1 along the X-axis direction, and a second interval L2 along the Y-axis direction as shown in FIG. 7. The second interval L2 is preferably formed to be smaller than the first interval L1, but may be formed to be greater than the first interval L1, or the same. The side wall SW is preferably formed of a first side wall and a second side wall SW1, SW2 facing each other with the same fourth height H4 as shown in FIGS. 32 and 34.

On the other hand, as shown in FIGS. 33 and 35, the sidewall SW is preferably formed of a third side wall and a fourth side wall SW3, SW4 facing each other with the same fifth height H5. Herein, the fifth height H5 of the third and the fourth side walls SW3, SW4 is formed to have a size different from the fourth height H4 of the first and the second side walls SW1, SW2. Because of this, the first and the second side walls SW1, SW2 are formed to be shorter than the third and the fourth side walls SW3, SW4 of FIG. 31, to have a step difference D3, and the third and the fourth side walls SW3, SW4 are formed to be shorter than the side walls of FIG. 31, to have a step difference D4.

Particularly, if the storage node 490 is formed to have an inclined profile so that the upper width is greater than the lower width, the actual intervals between the two adjacent first and second side walls SW1, SW2 along the X-axis direction of FIG. 7, and between the two adjacent third and fourth side walls SW3, SW4 along the Y-axis direction of FIG. 7 is increased due to the step differences D3, D4 respectively. The structural characteristics can significantly decrease a probability of electrical bridges occurring between them compared to the conventional technology, even if the storage nodes 490 are fallen down.

The etch process 630 is performed to have an etching ratio with respect to the molding layer 390 and the sacrificial layer patterns 500. Then, after the etch process 630 is performed, the photoresist layer 600 is removed from the semiconductor substrate 50. A wet etch process is performed by using the etch stop layer 360 as a buffer layer to remove the sacrificial layer patterns 500 and the molding layer 390, which contacts the inner sidewall and the outer sidewall of the storage node 490, respectively.

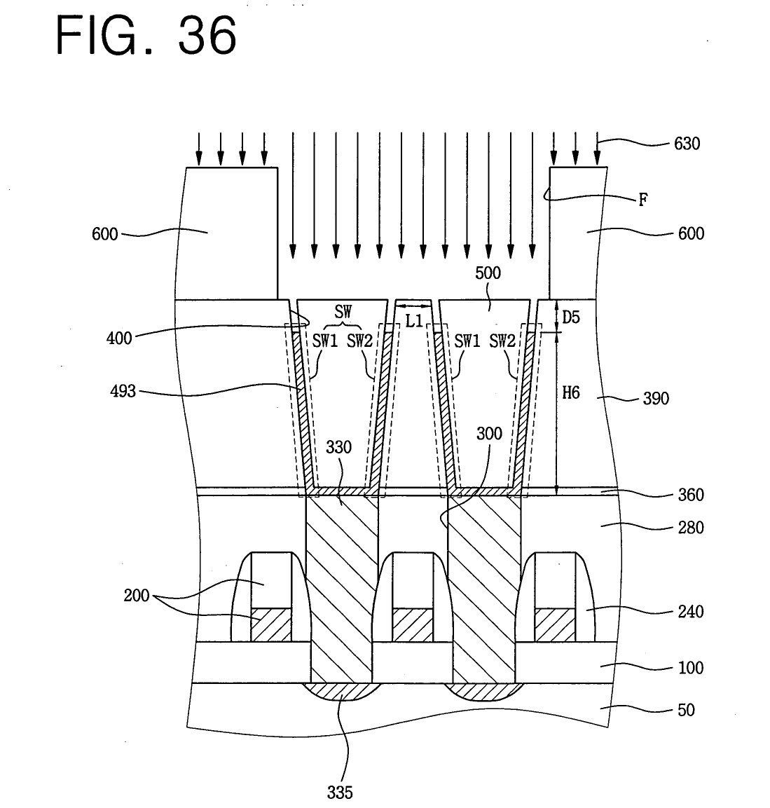

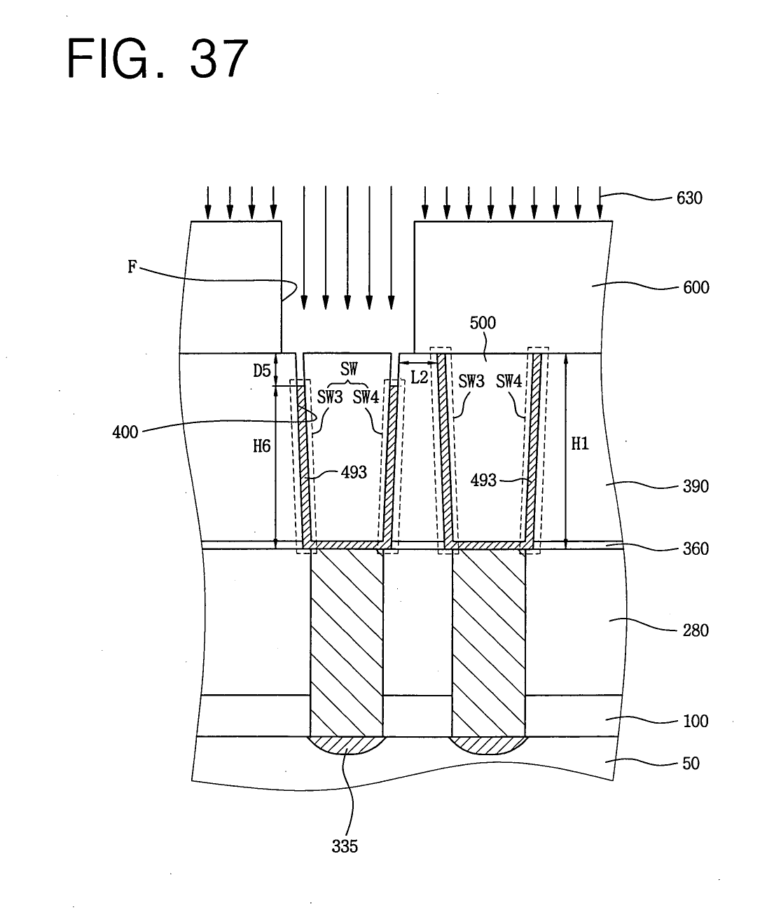

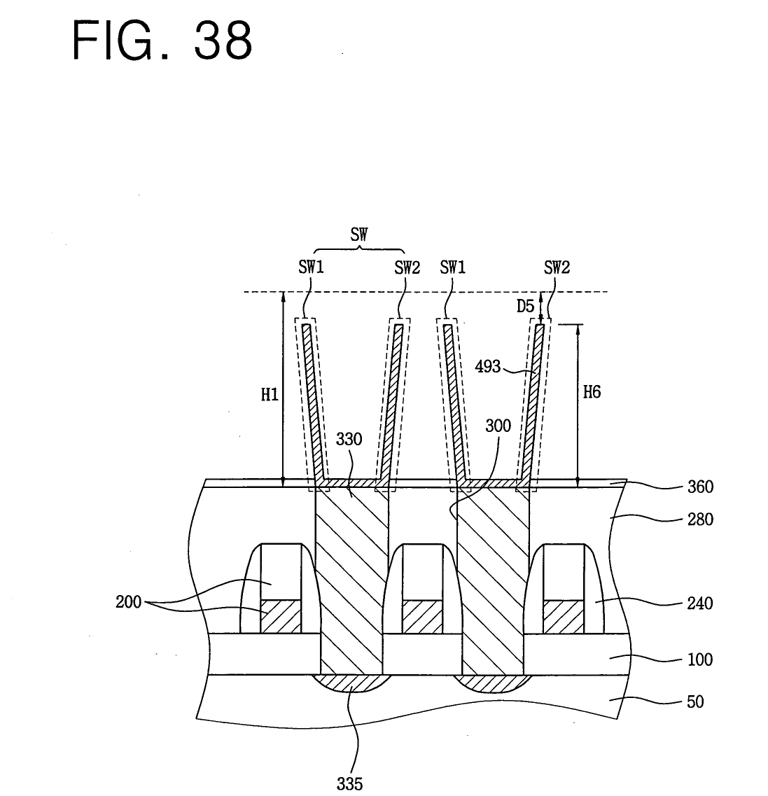

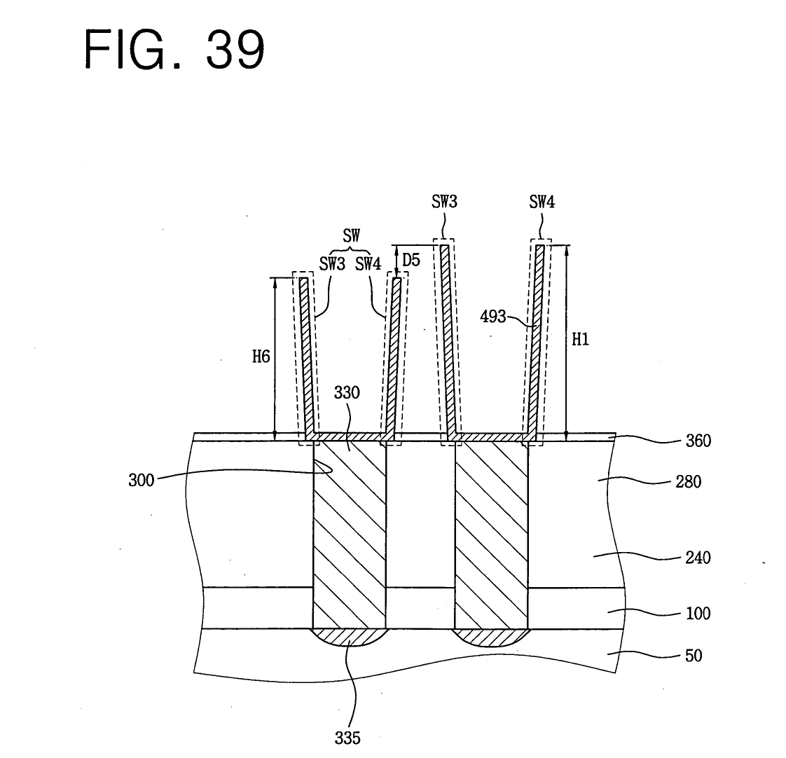

FIGS. 36 and 38 are sectional views taken along line I-I′ of FIG. 10, respectively, and FIGS. 37 and 39 are sectional views taken along line II-II′ of FIG. 10, respectively.

Referring to FIG. 10 and FIGS. 36 to 39, a photoresist layer 600 is formed on a semiconductor substrate 50 having the sacrificial layer patterns 500 of FIG. 23, and a photolithographic process is performed on the photoresist layer 600 to form storage openings F in the photoresist layer 600. The storage openings F are formed to expose the top surfaces of storage nodes placed on one extension line connecting the storage nodes 480 of FIG. 23. The storage openings F may be formed to expose the other storage nodes placed on every two lines in parallel with the one extension line. Then, an etch process 630 is performed on the photoresist layer having the storage openings F to partially remove the storage nodes 480 to a predetermined depth, and to form storage nodes 493. Each of the storage nodes 493 is formed to have an inclined profile so that the upper width is greater than the lower width.

In further detail, describing the storage nodes 493 of FIG. 10 according to an aspect of the invention, a plurality of cylindrical-type storage nodes 493 are formed over the semiconductor substrate 50, and formed to be in a two-dimensional array along columns and rows. The storage nodes 493 are formed to include a first group of storage nodes along the even rows, and a second group of storage nodes along the odd rows. Herein, the storage openings F preferably overlap the first group of storage nodes.

The intervals between the storage nodes 493 include a first interval L1 along the X-axis direction, and a second interval L2 along the Y-axis direction as shown in FIG. 10. The second interval L2 is preferably formed to be smaller than the first interval L1, but may be formed to be greater than the first interval L1, or the same. The sidewall SW is preferably formed to include a first side wall and a second side wall SW1, SW2 facing each other with the same sixth height H6 as shown in FIGS. 36 and 38.

On the other hand, as shown in FIGS. 37 and 39, the first and the second storage nodes in order to the right from the left have heights different from each other. That is, the first storage node has a third side wall and a fourth side wall SW3, SW4 having a sixth height H6, and the second storage node has a third side wall and a fourth side wall SW3, SW4 having a first height H1. Herein, the fourth side wall SW4 of the first storage node is adjacent to the third side wall SW3 of the second storage node. There exists a step difference D5 between the storage nodes 493.

Particularly, if the sidewall SW of the storage node 493 has an inclined profile so that the upper width is greater than the lower width, the actual intervals between the two adjacent third and the fourth side walls SW3, SW4, as well as between the two adjacent first and the second side walls SW1, SW2, are increased due to the step difference D5. Thus, even if the storage nodes 493 are fallen down, the probability of electrical bridges occurring between them is significantly decreased as compared to the conventional technology.

Alternatively, a plurality of cylindrical-type storage nodes 493 may be formed to be in a two-dimensional array along columns and rows over the semiconductor substrate 50 as shown in FIG. 13. Herein, the storage nodes 493 are formed to include a first group of storage nodes, which are placed on the cross locations of even rows and even columns as well as odd rows and odd columns, and a second group of storage nodes, which are placed on the cross locations of even rows and odd columns as well as odd rows and even columns other than the above, and adjacent to the first group of storage nodes. Herein, the first group of storage nodes are overlapped with the storage openings G of FIG. 13.

The etch process 630 is performed to have an etching ratio with respect to the molding layer 390 and the sacrificial layer patterns 500. Then, after the etch process 630 is performed, the photoresist layer 600 is removed from the semiconductor substrate 50. A wet etch process is performed by using the etch stop layer 360 as a buffer layer to remove the sacrificial layer patterns 500 and the molding layer 390, which contact the inner sidewall and the outer sidewall of the storage nodes 493, respectively.

According to the invention as described above, at least one of the cylindrical-type storage nodes is formed to have a step difference of its side walls in profile so as to avoid electrical bridges between one storage node and its adjacent storage node, which may occur due to the semiconductor fabrication process. As a result, semiconductor devices having the storage nodes can be fabricated from the semiconductor substrate with a high production yield, and the semiconductor devices can satisfy the desires of users, and contribute to the creation of future value for users.

According to another aspect of the present invention, although the present invention has been described in connection with a cylindrical-type sidewall of the storage node, other shapes may be used within the spirit and scope of the present invention. Thus, a sidewall extending from a rim of a bottom of the storage node may not necessarily be a cylindrical-type sidewall.

Embodiments of the invention will now be described in a non-limiting way.

Embodiments of the invention provide semiconductor devices having at least one storage node and methods of fabricating thereof.

According to some embodiments of the invention, there is provided a semiconductor device having at least one storage node that includes a semiconductor substrate. a storage node is formed over the semiconductor substrate. The storage node has a bottom portion and a cylindrical-typed sidewall (the cylindrical-typed sidewall will be referred to as “sidewall”.) extending upward from the rim of the bottom portion, at least a part of the sidewall being recessed.

According to some embodiments of the invention, there is provided a semiconductor device having at least one storage node that includes a semiconductor substrate. a plurality of cylindrical-typed storage nodes are arrayed in a two-dimension along the columns and the rows over the semiconductor substrate. Each of the storage nodes has a first side wall and a second side wall in parallel with the rows and facing to each other, and a third side wall and a fourth side wall in parallel with the columns and facing to each other. And at least one of the first and the second side walls of the storage nodes is lower in height than the third and the fourth side walls.

According to some embodiments of the invention, there is provided a semiconductor device having at least one storage node that includes a semiconductor substrate. A plurality of storage nodes are placed over the semiconductor substrate. The storage nodes have bottom portions and a cylindrical-typed sidewalls respectively extending upward from the rim of the bottom portions. Each of the storage nodes has the same height along the rim of the sidewall, and two adjacent ones of the storage nodes have the side walls having heights different from each other.

According to the other embodiments of the invention, there is provided a semiconductor device having at least one storage node that includes a semiconductor substrate. a plurality of cylindrical-typed storage nodes are arrayed in a two-dimension along the columns and the rows over the semiconductor substrate. The storage nodes have a first group of storage nodes arrayed along the even rows, and a second group of storage nodes arrayed along the odd rows. And the first group of the storage nodes are lower in height than the second group of the storage nodes.

According to the other embodiments of the invention, there is provided a semiconductor device having at least one storage node that includes a semiconductor substrate. a plurality of cylindrical-typed storage nodes are arrayed in a two-dimension along the columns and the rows over the semiconductor substrate. The storage nodes have a first group of storage nodes, which are placed on cross locations of even rows and even columns as well as odd rows and odd columns, and a second group of storage nodes, which are placed on the other cross locations of even rows and odd columns as well as odd rows and even columns, and adjacent to the first group of storage nodes. The first group of storage nodes are lower in height than the second group of storage nodes.

According to some embodiments of the invention, there is provided a method of fabricating a semiconductor device having at least one storage node that includes forming a molding layer over a semiconductor substrate. A storage contact hole is formed to penetrate the molding layer. A storage node and a sacrificial layer pattern are sequentially stacked in the storage contact hole. At this time, the storage node is conformally formed in the storage contact hole. The top surface of the storage node is exposed between the molding layer and the sacrificial layer pattern. A photoresist layer is formed on the semiconductor substrate having the sacrificial layer pattern and the molding layer. The photoresist layer has a storage opening. An etch process is performed on the storage node through the storage opening by using the photoresist layer as an etch mask. The storage opening exposes the top surface of the storage node, and the etch process is performed to partially remove the storage node.

According to some embodiments of the invention, there is provided a method of fabricating a semiconductor device having at least one storage node that includes forming a molding layer on a semiconductor substrate. A plurality of storage contact holes are formed to penetrate the molding layer. Storage nodes and sacrificial layer patterns are sequentially stacked in the storage contact holes. The top surfaces of the storage nodes are exposed between the molding layer and the sacrificial layer patterns. A photoresist layer are formed on the semiconductor substrate having the sacrificial layer patterns and the molding layer. The photoresist layer has storage openings. An etch process is performed on the storage nodes through the storage openings by using the photoresist layer as an etch mask. The storage openings are formed to expose the top surfaces of the storage nodes, and the etch process is performed to partially remove the storage nodes.

While the invention has been particularly shown and described with reference to exemplary embodiments thereof, it will be understood by those skilled in the art that the foregoing and other changes in form and details may be made therein without departing from the spirit and scope of the invention as defined in the following claims.

1. A semiconductor device comprising:
a semiconductor substrate; and
a storage node formed over the semiconductor substrate, and having a bottom portion and a sidewall extending upward from a rim of the bottom portion, at least a portion of the sidewall being recessed.

2. The semiconductor device according to claim 1, wherein the sidewall includes two pairs of side walls, the side walls in each pair facing each other, and at least one of the four side walls being lower in height than the remaining side walls.

3. The semiconductor device according to claim 1, wherein the sidewall of the storage node has an inclined profile so that an upper width of the storage node is greater than a lower width of the storage node.

4. The semiconductor device according to claim 1, further comprising, between the bottom portion of the storage node and the semiconductor substrate,
a bit line interlayer insulating layer covering the semiconductor substrate;
two adjacent bit line patterns placed on the bit line interlayer insulating layer, each bit line pattern having a bit line and a bit line capping layer pattern stacked thereon; and
a buried contact hole pad placed in the bit line interlayer insulating layer between the bit line patterns, and electrically connected to the bottom portion and the semiconductor substrate.

5. The semiconductor device according to claim 4, further comprising, between the bit line interlayer insulating layer and the bottom portion,
a buried interlayer insulating layer placed on the bit line interlayer insulating layer, covering the bit line patterns and surrounding the buried contact hole pad; and
an etch stop layer placed on the buried interlayer insulating layer and surrounding the bottom portion.

6. The semiconductor device according to claim 4, wherein the storage node comprises a conductive layer having substantially the same etching ratio as the buried contact hole pad.

7. The semiconductor device according to claim 5, wherein the etch stop layer comprises an insulating layer having an etching ratio different from that of the buried interlayer insulating layer.

8. The semiconductor device according to claim 5, wherein the buried interlayer insulating layer includes an insulating layer having substantially the same etching ratio as the bit line interlayer insulating layer.

9. The semiconductor device according to claim 4, further comprising, between the bit line patterns, bit line spacers respectively contacting the buried contact hole pad, and covering the side walls of the bit line patterns.

10. A semiconductor device comprising:
a semiconductor substrate; and
a plurality of cylindrical-type storage nodes in a two-dimensional array along columns and rows over the semiconductor substrate, each of the storage nodes having a first side wall and a second side wall in parallel with the rows and facing each other, and a third side wall and a fourth side wall in parallel with the columns and facing each other, and at least one of the first and the second side walls of the storage nodes being lower in height than the third and the fourth side walls.

11. The semiconductor device according to claim 10, wherein each of the storage nodes has an inclined profile so that an upper width of the first to the fourth side walls is greater than a lower width thereof.

12. A semiconductor device comprising:
a semiconductor substrate; and
a plurality of storage nodes placed over the semiconductor substrate, the plurality of storage nodes having bottom portions and cylindrical-type sidewalls respectively extending upward from a rim of the bottom portions,
each of the storage nodes having substantially the same height along the rim of the sidewall, and two adjacent storage nodes having the side walls being different heights from each other.

13. The semiconductor device according to claim 12, further comprising, between the bottom portions of the storage nodes and the semiconductor substrate,
a bit line interlayer insulating layer covering the semiconductor substrate;
bit line patterns placed on the bit line interlayer insulating layer, each bit line pattern having a bit line and a bit line capping layer pattern stacked thereon; and
buried contact hole pads placed in the bit line interlayer insulating layer between the bit line patterns, and electrically connected to the bottom portions and the semiconductor substrate.

14. The semiconductor device according to claim 13, further comprising, between the bit line interlayer insulating layer and the bottom portions,
a buried interlayer insulating layer placed on the bit line interlayer insulating layer, covering the bit line patterns and surrounding the buried contact hole pads; and
an etch stop layer placed on the buried interlayer insulating layer and surrounding the bottom portions.

15. The semiconductor device according to claim 13, wherein the storage nodes comprise a conductive layer having substantially the same etching ratio as the buried contact hole pads.

16. The semiconductor device according to claim 14, wherein the etch stop layer comprises an insulating layer having an etching selectivity with respect to the buried interlayer insulating layer.

17. The semiconductor device according to claim 14, wherein the buried interlayer insulating layer comprises an insulating layer having substantially the same etching ratio as the bit line interlayer insulating layer.

18. The semiconductor device according to claim 13, further comprising, between the bit line patterns, bit line spacers respectively contacting the buried contact hole pads, and covering the side walls of the bit line patterns.

19. A semiconductor device comprising:
a semiconductor substrate; and
a plurality of cylindrical-type storage nodes in a two-dimensional array along columns and rows over the semiconductor substrate, the storage nodes having a first group of storage nodes along the even rows, and a second group of storage nodes along the odd rows, and the first group of the storage nodes being lower in height than the second group of the storage nodes.

20. The semiconductor device according to claim 19, wherein each of the storage nodes has an inclined profile so that an upper width is greater than a lower width.

21. A semiconductor device comprising:
a semiconductor substrate; and
a plurality of cylindrical-type storage nodes in a two-dimensional array along columns and rows over the semiconductor substrate, the storage nodes having a first group of storage nodes, which are placed on cross locations of even rows and even columns as well as odd rows and odd columns, and a second group of storage nodes, which are placed on the other cross locations of even rows and odd columns as well as odd rows and even columns, and adjacent to the first group of storage nodes, the first group of storage nodes being lower in height than the second group of storage nodes.

22. The semiconductor device according to claim 21, wherein each of the storage nodes has an inclined profile so that an upper width is greater than a lower width.

23. A method of fabricating a semiconductor device, the method comprising:
forming a molding layer over a semiconductor substrate;
forming a storage contact hole penetrating the molding layer;
forming a storage node and a sacrificial layer pattern sequentially stacked in the storage contact hole, the top surface of the storage node being exposed between the molding layer and the sacrificial layer pattern;
forming a photoresist layer on the semiconductor substrate having the sacrificial layer pattern and the molding layer, the photoresist layer having a storage opening; and
performing an etch process on the storage node to partially remove the storage node through the storage opening, using the photoresist layer as an etch mask, the storage opening exposing the top surface of the storage node.

24. The method according to claim 23, wherein the storage node is formed to include an inclined profile so that an upper width is greater than a lower width.

25. The method according to claim 23, wherein the storage node is formed to include two pairs of side walls, the side walls of each of the two pairs facing each other, and
the storage opening overlaps at least one among the side walls to expose the top surface of the storage node.

26. The method according to claim 23, wherein the storage node is formed to include two pairs of side walls, the side walls of each of the two pairs facing each other, and
the storage opening overlaps one pair of the facing side walls to expose the top surface of the storage node.

27. The method according to claim 23, wherein the storage node is formed to include two pairs of side walls, the side walls of each of the two pairs facing each other, and
the storage opening overlaps two pairs of the facing side walls at the same time to expose the top surface of the storage node.

28. The method according to claim 23, wherein the sacrificial layer pattern is formed of an insulating layer having substantially the same etching ratio as the molding layer.

29. The method according to claim 23, wherein the storage node is formed of a conductive layer.

30. The method according to claim 23, further comprising:
before forming the molding layer,
forming an etch stop layer under the molding layer; and
forming the storage contact hole to extend into the etch stop layer.

31. The method according to claim 23, further comprising:
after performing the etch process,
removing the photoresist layer having the storage opening; and
removing the sacrificial layer pattern and the molding layer, leaving the storage nodes over the semiconductor substrate.

32. The method according to claim 23, wherein
the forming the storage node and the sacrificial layer pattern comprises:
conformably forming a storage node layer on the semiconductor substrate having the storage contact hole;
forming a sacrificial layer to fill the storage contact hole on the storage node layer; and
performing a planarization process until the top surface of the molding layer is exposed, to sequentially etch the sacrificial layer and the storage node layer.

33. The method according to claim 23, wherein the etch process is performed to have an etching selectivity with respect to the molding layer and the sacrificial layer pattern.

34. The method according to claim 23, further comprising:
before forming the molding layer,
forming two adjacent bit line patterns on the semiconductor substrate having a bit line interlayer insulating layer;
forming a buried interlayer insulating layer covering the bit line patterns;
forming a buried contact hole penetrating the buried interlayer insulating layer on a predetermined portion between the bit line patterns; and
filling the buried contact hole with a buried contact hole pad, the buried contact hole pad being electrically connected to the storage node, and being overlapped with the storage opening over the pad at substantially the same time.

35. A method of fabricating a semiconductor device, the method comprising:
forming a molding layer on a semiconductor substrate;
forming a plurality of storage contact holes penetrating the molding layer;
forming storage nodes and sacrificial layer patterns sequentially stacked in the storage contact holes, the top surfaces of the storage nodes being exposed between the molding layer and the sacrificial layer patterns;
forming a photoresist layer on the semiconductor substrate having the sacrificial layer patterns and the molding layer, the photoresist layer having storage openings; and
performing an etch process on the storage nodes through the storage openings to partially remove the storage nodes, using the photoresist layer as an etch mask, wherein the storage openings are formed to expose the top surfaces of the storage nodes.

36. The method according to claim 35, wherein each of the storage nodes is formed to have an inclined profile so that an upper width is greater than a lower width.

37. The method according to claim 35, wherein the storage nodes are formed in a two-dimensional array over the semiconductor substrate along columns and rows, and each of the storage nodes is formed to include a first side wall and a second side wall, which are in parallel with the rows and face each other, and a third side wall and a fourth side wall, which are in parallel with the columns and face each other; and
each of the storage openings overlaps one selected among the four side walls.

38. The method according to claim 35, wherein the storage nodes are formed in a two-dimensional array over the semiconductor substrate along columns and rows, and the storage nodes are formed to have a first group of storage nodes along the even rows, and a second group of storage nodes along the odd rows; and
the storage openings overlap the first group of storage nodes, respectively.

39. The method according to claim 35, wherein the storage nodes are formed in a two-dimensional array over the semiconductor substrate along columns and rows, and the storage nodes are formed to have a first group of storage nodes, which are placed on cross locations of even rows and even columns as well as odd rows and odd columns, and a second group of storage nodes, which are placed on the other cross locations of the rows and the columns other than the above, and adjacent to the first group of storage nodes, the storage openings overlapping the first group of storage nodes, respectively.

40. The method according to claim 35, wherein the sacrificial layer patterns are formed of an insulating layer having substantially the same etching ratio as the molding layer.

41. The method according to claim 35, wherein the storage nodes are formed of a conductive layer.

42. The method according to claim 35, further comprising:
before forming the molding layer,
forming an etch stop layer under the molding layer; and
forming the storage contact holes to extend into the etch stop layer.

43. The method according to claim 35, further comprising:
after performing the etch process,
removing the photoresist layer having the storage openings; and
removing the sacrificial layer patterns and the molding layer, leaving the storage nodes over the semiconductor substrate.

44. The method according to claim 35, wherein forming the storage nodes and the sacrificial layer patterns comprises:
conformably forming a storage node layer on the semiconductor substrate having the storage contact holes;
forming a sacrificial layer to fill the storage contact holes on the storage node layer; and
performing a planarization process until the top surface of the molding layer is exposed, to sequentially etch the sacrificial layer and the storage node layer.

45. The method according to claim 35, wherein the etch process has an etching selectivity with respect to the molding layer and the sacrificial layer pattern.

46. The method according to claim 35, further comprising:
before forming the molding layer,
forming bit line patterns on the semiconductor substrate having a bit line interlayer insulating layer;
forming a buried interlayer insulating layer covering the bit line patterns;
forming buried contact holes penetrating the buried interlayer insulating layer, and located on predetermined portions between the bit line patterns; and
filling the buried contact holes with buried contact hole pads, wherein the buried contact hole pads are electrically connected to the storage nodes, and being overlapped with the storage openings on top of the pads.
